(19) United States
(12) Patent Application Publication
(10) Pub. No.: US 2026/0188182 A1
(43) Pub. Date: Jul. 2, 2026

(54) DISPLAY PANEL AND DISPLAY DEVICE

(71) Applicant: Tianma Advanced Display Technology Institute (Xiamen) Co.,Ltd., Xiamen (CN)

(72) Inventors: Fanqing MENG, Xiamen (CN); Bo YANG, Xiamen (CN); Zhenyu JIA, Xiamen (CN); Wenxin JIANG, Xiamen (CN)

(21) Appl. No.: 19/213,026

(22) Filed: May 20, 2025

(30) Foreign Application Priority Data
Dec. 30, 2024 (CN) 202411982714.7

(51) Int. Cl. G09G 3/32; G09G 3/3225

(52) U.S. Cl. CPC G09G 3/32; G09G 3/3225; G09G 2300/0426; G09G 2310/0286; G09G 2330/06

(57) ABSTRACT

A display panel and a display device are provided. The display panel includes: The display panel includes first line segments, second line segments, and pixel circuits. At least one end of one first line segment is a cut-off end. Two ends of one second line segment are non-cut-off ends. One second line segment is electrically connected to one corresponding pixel circuit. The display panel has a first area and a second area. The first area is located on a side of the second area close to an edge of the display panel. The pixel circuits are disposed in the second area; and the first line segments are located in the first area.

### CROSS-REFERENCE TO RELATED APPLICATION

This application claims the priority of Chinese Patent Application No. 202411982714.7, filed on Dec. 30, 2024, the content of which is incorporated herein by reference in its entirety.

### TECHNICAL FIELD

The present disclosure generally relates to the field of display technology and, more particularly, relates to a display panel and a display device.

### BACKGROUND

Electrostatic protection is one of the main research topics in the display field. Static electricity may damage components in a display panel and affect the display performance of the display panel. How to provide reliable electrostatic protection in the display panel is a technical problem that technicians in this field need to solve urgently.

### SUMMARY

One aspect of the present disclosure provides a display panel. The display panel includes: The display panel includes first line segments, second line segments, and pixel circuits. At least one end of one first line segment is a cut-off end. Two ends of one second line segment are non-cut-off ends. One second line segment is electrically connected to one corresponding pixel circuit. The display panel has a first area and a second area. The first area is located on a side of the second area close to an edge of the display panel. The pixel circuits are disposed in the second area; and the first line segments are located in the first area.

Another aspect of the present disclosure provides a display device. The display device includes a display panel. The display panel includes: The display panel includes first line segments, second line segments, and pixel circuits. At least one end of one first line segment is a cut-off end. Two ends of one second line segment are non-cut-off ends. One second line segment is electrically connected to one corresponding pixel circuit. The display panel has a first area and a second area. The first area is located on a side of the second area close to an edge of the display panel. The pixel circuits are disposed in the second area; and the first line segments are located in the first area.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a top view of an exemplary display panel consistent with various disclosed embodiments in the present disclosure.

FIG. 2 illustrates a partial top view of an exemplary display panel consistent with various disclosed embodiments in the present disclosure.

FIG. 3 illustrates a top view of a display panel.

FIG. 4 illustrates a top view of another exemplary display panel consistent with various disclosed embodiments in the present disclosure.

FIG. 5 illustrates a schematic electrical connection of pixel circuits and driving circuits in a CC′ region of an exemplary display panel in FIG. 1, consistent with various disclosed embodiments in the present disclosure.

FIG. 6 illustrates a schematic diagram of a pixel circuit.

FIG. 7 illustrates a top view of another exemplary display panel consistent with various disclosed embodiments in the present disclosure.

FIG. 8 illustrates an enlarged view of a KK′ region of an exemplary display panel in FIG. 7, consistent with various disclosed embodiments in the present disclosure.

FIG. 9 illustrates a top view of another exemplary display panel consistent with various disclosed embodiments in the present disclosure.

FIG. 10 illustrates an enlarged view of a KK′ region of an exemplary display panel in FIG. 9, consistent with various disclosed embodiments in the present disclosure.

FIG. 11 illustrates a partially cross-sectional view of another exemplary display panel consistent with various disclosed embodiments in the present disclosure.

FIG. 12 illustrates a partially cross-sectional view of another exemplary display panel consistent with various disclosed embodiments in the present disclosure.

FIG. 13 illustrates a partially cross-sectional view of another exemplary display panel consistent with various disclosed embodiments in the present disclosure.

FIG. 14 illustrates an enlarged view of a KK′ region of an exemplary display panel in FIG. 13, consistent with various disclosed embodiments in the present disclosure.

FIG. 15 illustrates an enlarged view of an edge region of an exemplary display panel along a first direction, consistent with various disclosed embodiments in the present disclosure.

FIG. 16 illustrates an enlarged view of an edge region of another exemplary display panel along a first direction, consistent with various disclosed embodiments in the present disclosure.

FIG. 17 illustrates an enlarged view of an edge region of another exemplary display panel along a first direction, consistent with various disclosed embodiments in the present disclosure.

FIG. 18 illustrates an enlarged view of an edge region of another exemplary display panel along a first direction, consistent with various disclosed embodiments in the present disclosure.

FIG. 19 illustrates another exemplary pixel circuit consistent with various disclosed embodiments in the present disclosure.

FIG. 20 illustrates an enlarged view of an edge region of another exemplary display panel along a first direction, consistent with various disclosed embodiments in the present disclosure.

FIG. 21 illustrates an enlarged view of an edge region of another exemplary display panel along a first direction, consistent with various disclosed embodiments in the present disclosure.

FIG. 22 illustrates a top view of another exemplary display panel consistent with various disclosed embodiments in the present disclosure.

FIG. 23 illustrates an enlarged view of a layout structure of an EE′ region in FIG. 22 consistent with various disclosed embodiments in the present disclosure.

FIG. 24 illustrates an enlarged view of a layout structure of an FF′ region in FIG. 22 consistent with various disclosed embodiments in the present disclosure.

FIG. 25 illustrates another enlarged view of a layout structure of an EE′ region in FIG. 22 consistent with various disclosed embodiments in the present disclosure.

FIG. 26 illustrates another enlarged view of a layout structure of an FF′ region in FIG. 22 consistent with various disclosed embodiments in the present disclosure.

FIG. 27 illustrates another enlarged view of a layout structure of an EE′ region in FIG. 22 consistent with various disclosed embodiments in the present disclosure.

FIG. 28 illustrates another enlarged view of a layout structure of an FF′ region in FIG. 22 consistent with various disclosed embodiments in the present disclosure.

FIG. 29 illustrates another enlarged view of a layout structure of an EE′ region in FIG. 22 consistent with various disclosed embodiments in the present disclosure.

FIG. 30 illustrates another enlarged view of a layout structure of an FF′ region in FIG. 22 consistent with various disclosed embodiments in the present disclosure.

FIG. 31 illustrates a schematic diagram showing a situation in which a cut-off end of a first line segment close to a third region overlaps with a second conductive component in a direction perpendicular to the plane where the display panel is located.

FIG. 32 illustrates another enlarged view of a layout structure of an EE′ region in FIG. 22 consistent with various disclosed embodiments in the present disclosure.

FIG. 33 illustrates an exemplary display device consistent with various disclosed embodiments in the present disclosure.

FIG. 34 illustrates another exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

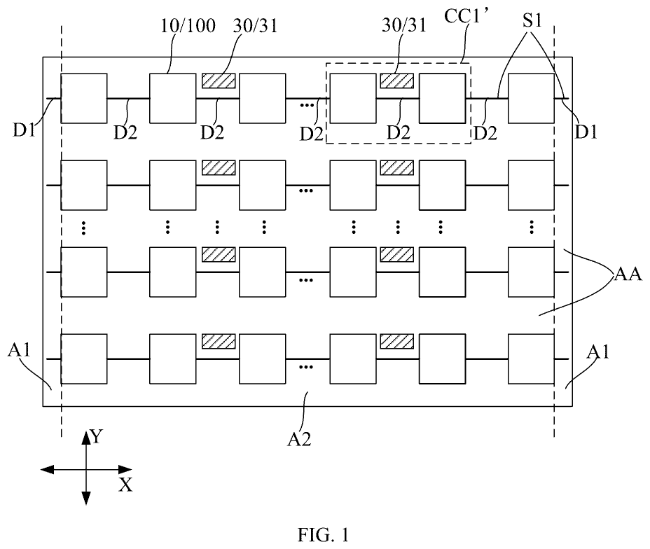

The present disclosure provides a display panel. In one embodiment shown in FIG. 1 which is a top view of a display panel provided by the present embodiment, the display panel may include first line segments D1, second line segments D2, and pixel circuits 10. For one first line segment D1, one end of the first line segment D1 may be a cut-off end, and another end of the first line segment D1 may be connected to one corresponding second line segment D2. For one the second line segment D2, two ends may be non-cut-off ends, and the second line segment D2 may be electrically connected to one corresponding pixel circuit 10.

As shown in FIG. 1, the display panel may also include first signal lines S1, and one first signal line S1 may include first line segments D1 and second line segments D2. That is, the first line segments D1 and the second line segments D2 may be two portions of segments in the first signal line S1, the second line segments D2 are the middle segments of the first signal line S1, and the first line segments D1 are segments at two ends of the first signal line S1. The first line segments D1 and the second line segments D2 may be connected. For one first line segment D1, one end of the first line segment D1 away from one corresponding second line segment D2 may be the cut-off end, and the cut-off end of the first line segment D1 may be also the cut-off end of the corresponding first signal line S1.

Since the second line segment D2 is electrically connected to the corresponding pixel circuit 10 and the first line segment D1 is connected to the corresponding second line segment D2, the first signal line S1 and the first line segment D1 may also be electrically connected to the corresponding pixel circuit 10. The first signal line S1 may be used to transmit a signal to the corresponding pixel circuit 10.

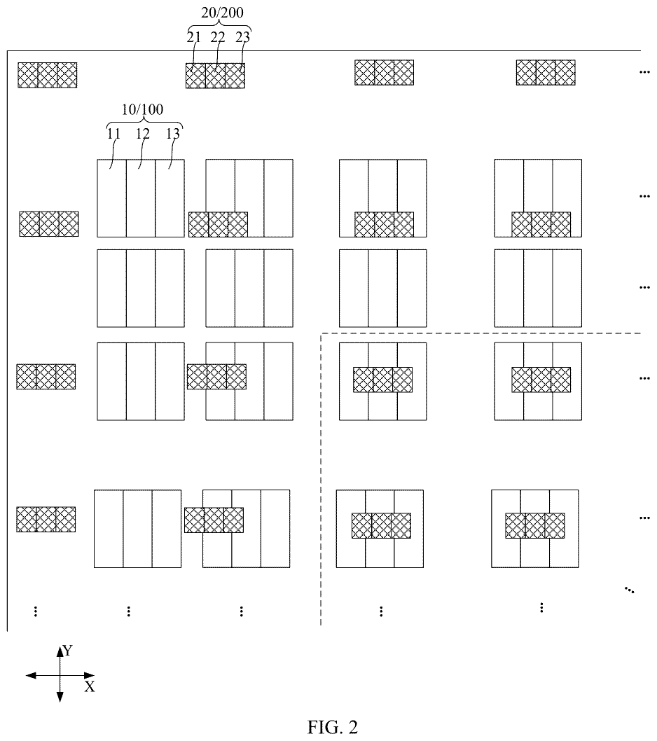

FIG. 2 shows a partial top view schematic diagram of a display panel consistent with the present disclosure. As shown in FIG. 2, in one embodiment, the display panel may include light-emitting elements 20, and one pixel circuit 10 may be electrically connected to one corresponding light-emitting element 20 accordingly. The pixel circuit 10 may be used to drive the light-emitting diode 20 to emit light.

Optionally, in one embodiment, the light-emitting element 20 may be an organic light-emitting diode (OLED), or a micro light-emitting diode such as a sub-millimeter light-emitting diode (Mini-LED) or a micro light-emitting diode (Micro-LED). As shown in FIG. 2, the display panel may include pixel circuit groups 100, and one pixel circuit group 100 may include at least two pixel circuits 10. The pixel circuit groups 100 may be arranged in a row along a first direction X, and multiple rows of pixel circuit groups 100 may be arranged along a second direction Y. The first direction X and the second direction Y may intersect, and the first direction X and the second direction Y may be parallel to the plane where the display panel is located. Correspondingly, as shown in FIG. 2, the display panel may also include light-emitting element groups 200, one light-emitting element group 200 may include at least two light-emitting elements 20, the light-emitting element groups 200 may be also arranged in a row along the first direction X, and multiple rows of light-emitting element groups 200 may also be arranged along the second direction Y. The pixel circuit groups 100 and the light-emitting element groups 200 may be electrically connected accordingly.

As shown in FIG. 2, the light-emitting elements 20 may include first light-emitting elements 21, second light-emitting elements 22 and third light-emitting elements 23. The first light-emitting elements 21 may be used to emit red light, the second light-emitting elements 22 may be used to emit green light, and the third light-emitting elements 23 may be used to emit blue light. One light-emitting element group 200 may include one first light-emitting element 21, one second light-emitting element 22 and one third light-emitting element 23. Correspondingly, as shown in FIG. 2, one pixel circuit group 100 may include a first pixel circuit 11 for driving the first light-emitting element 21 to emit light, a second pixel circuit 12 for driving the second light-emitting element 22 to emit light, and a third pixel circuit 13 for driving the third light-emitting element 23 to emit light.

To enable the pixel circuits 10 to drive the light-emitting elements 20 to emit light, the display panel may also include driving circuits 30, and one driving circuit 30 may be used to provide a driving signal to one corresponding pixel circuit 10.

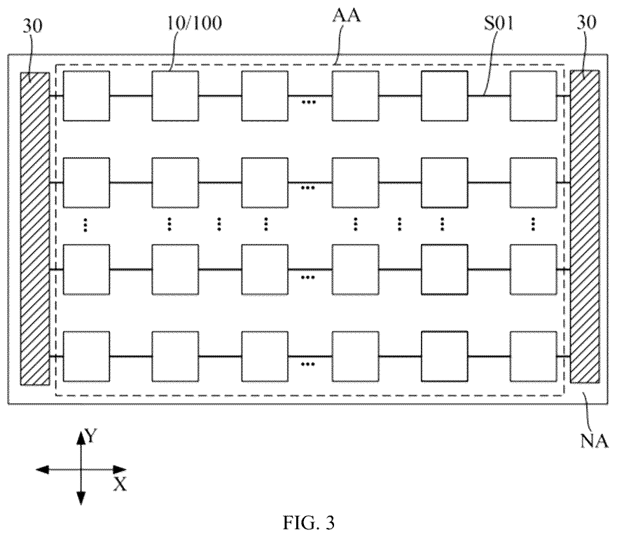

FIG. 3 shows a schematic top view of an existing display panel. As shown in FIG. 3, the display panel includes a display area AA and a non-display area NA at least partially surrounding the display area AA. The driving circuits 30 are located in the non-display area NA, and the driving circuits 30 are located on at least one side of the display area AA along the first direction X. The driving circuits 30 provides a driving signal to each row of pixel circuits 10 through a signal line S01 extending along the first direction X. It can be seen that the driving circuits 30 occupies the left frame area and/or the right frame area of the display panel. With the continuous development of display technology, narrow frame display, extremely narrow frame display and borderless display have gradually become mainstream displays. Based on this, at least one driving circuit 30 may be disposed in the display area AA to achieve a narrow frame, an extremely narrow frame or even a borderless design.

As shown in FIG. 1 and FIG. 2, in the display panel provided by some embodiments of the present disclosure, the display area AA may include not only the pixel circuits 10 and the light-emitting elements 20, but also at least one driving circuit 30. Further, to arrange the at least one driving circuit 30 in the display area AA, considering that the pixel circuits 10 needs to have a certain distance from the frame of the display panel, as shown in FIG. 2, in the edge area of the display area AA, the pixel circuit 10 and the corresponding electrically connected light-emitting element 20 may not overlap in the direction perpendicular to the plane where the display panel is located, and, in the middle area of the display area AA, the pixel circuit 10 and the corresponding electrically connected light-emitting element 20 may at least partially overlap in the direction perpendicular to the plane where the display panel is located. In other words, in the edge area of the display area AA, the pixel circuit group 100 and the corresponding electrically connected light-emitting element group 200 may not overlap in the direction perpendicular to the plane where the display panel is located, and, in the middle area of the display area AA, the pixel circuit group 100 and the corresponding electrically connected light-emitting element group 200 may at least partially overlap in the direction perpendicular to the plane where the display panel is located, such that a display panel with a narrow frame, an extremely narrow frame or even no frame is realized.

As shown in FIG. 1, the driving circuit 30 may include shift register circuits 31 in a multi-stage cascade arrangement. Optionally, the shift register circuits 31 may be located between different columns of pixel circuits 10, or in other words, the shift register circuits 31 may be located between different columns of pixel circuit groups 100.

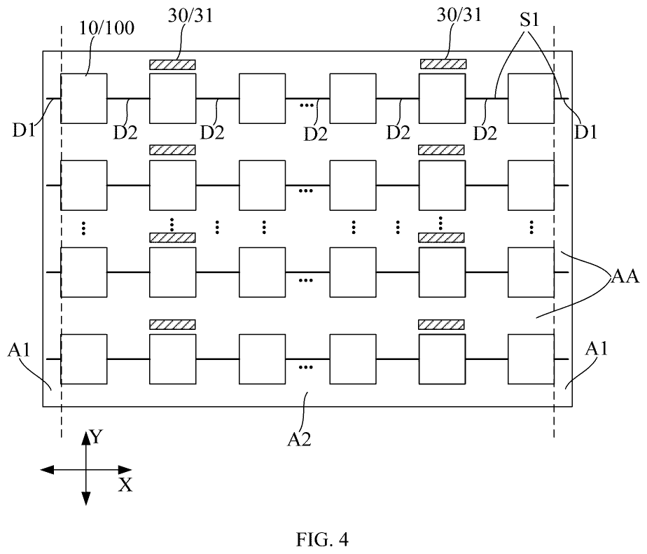

FIG. 4 shows a top view of another display panel provided by an embodiment of the present disclosure. As shown in FIG. 4, in another embodiment, the shift register circuits 31 may be located between different rows of pixel circuits 10, or in other words, the shift register circuits 31 may be located between different rows of pixel circuit groups 100.

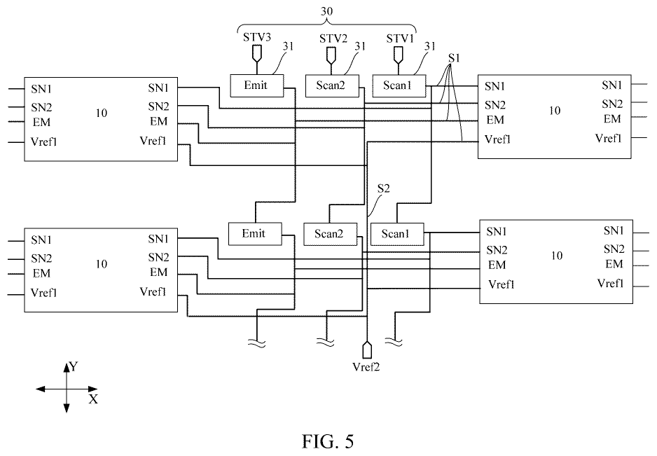

For better understanding, FIG. 5 shows a schematic diagram of an electrical connection relationship between the pixel circuits 10 and the driving circuits 30 in the CC′ area of the display panel shown in FIG. 1. As shown in FIG. 5, one driving circuit 30 may include a scanning circuit STV1, a scanning circuit STV2 and a light-emitting control circuit STV3. The scanning circuit STV1 may include a shift register circuit Scan1 arranged in a multi-stage cascade, and the shift register circuit Scan1 is electrically connected to one corresponding pixel circuit 10 through a scanning signal line SN1 extending along a first direction X; the scanning circuit STV2 includes a shift register circuit Scan2 arranged in a multi-stage cascade, and the shift register circuit Scan2 may be electrically connected to one corresponding pixel circuit 10 through a scanning signal line SN2 extending along the first direction X. The light-emitting control circuit STV3 may include a shift register circuit Emit arranged in a multi-stage cascade, and the shift register circuit Emit may be electrically connected to the corresponding pixel circuit 10 through a light-emitting control signal line EM extending along the first direction X. Further, as shown in FIG. 5, the display panel may further include a reference voltage signal line Vref1 and a reference voltage signal line Vref2. The reference voltage signal line Vref1 may extend along a first direction X, the reference voltage signal line Vref2 may extend along the second direction Y. The reference voltage signal line Vref1 and the reference voltage signal line Vref2 may be electrically connected, and the reference voltage signal line Vref1 may be electrically connected to the pixel circuit 10.

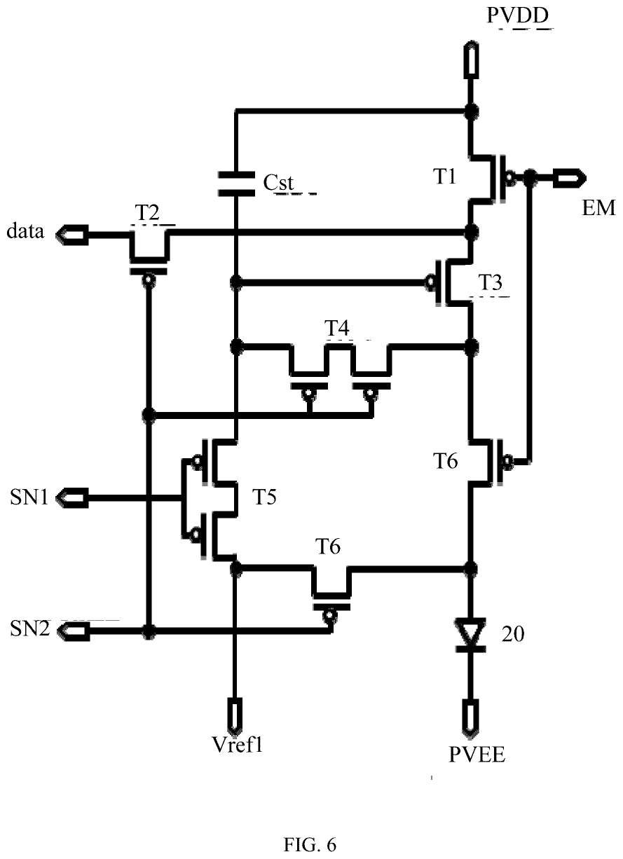

FIG. 6 shows a schematic diagram of a circuit structure of one pixel circuit 10. As shown in FIG. 6, in one embodiment, the pixel circuit 10 may be a 7T1C structure, and may include a first light emission control transistor T1, a data writing transistor T2, a driving transistor T3, a compensation transistor T4, a gate reset transistor T5, a second light emission control transistor T6, an anode reset transistor T7, and a storage capacitor Cst. The signal lines electrically connected to the pixel circuit 10 may include a scanning signal line SN1, a scanning signal line SN2, a light emission control signal line EM, a reference voltage signal line Vref1, a data signal line data, and a power supply voltage line PVDD. The pixel circuit 10 may be electrically connected to one electrode of the light-emitting element 20, and the other electrode of the light-emitting element 20 may be electrically connected to the power supply voltage line PVEE. The electrical connection relationship between the transistors in the 7T1C pixel circuit and the electrical connection relationship between the transistors and the signal lines are shown in FIG. 6 and will not be described in detail.

The pixel circuit 10 shown in FIG. 6 is only used as an example to illustrate the present disclosure, and does not limit the scope of the present disclosure. In practical applications, pixel circuits of other circuit structures may be selected based on demand.

Comparing FIG. 1 and FIG. 3, and comparing FIG. 3 and FIG. 4, it may be seen that, in the existing display panel, since the driving circuits 30 are located on at least one side of the display area AA along the first direction X, the signal lines electrically connecting the driving circuits 30 and each row of pixel circuits 10 extending along the first direction X are cut off at the driving circuits 30, that is, there are no cut-off ends. After the driving circuits 30 are set in the display area AA, since the driving circuits 30 are located in the display area AA, the two ends of the signal line electrically connecting the driving circuits 30 and each row of pixel circuits 10 extending along the first direction X may become cut-off ends.

Optionally, as shown in FIG. 1 and FIG. 4, the first signal line S1 may extend along the first direction X.

Further optionally, as shown in FIG. 5 and FIG. 6, in one embodiment, the first signal line S1 may be electrically connected to the shift register circuit 31, that is, the first signal line S1 may be a functional signal line electrically connecting the driving circuit 30 and the corresponding pixel circuit 10. For example, the first signal line S1 may be a scanning signal line SN1 electrically connecting the pixel circuit 10 and the shift register circuit Scan1. For another example, the first signal line S1 may also be a scanning signal line SN2 electrically connecting the pixel circuit 10 and the shift register circuit Scan2. For another example, the first signal line S1 may also be a light-emitting control signal line EM electrically connecting the pixel circuit 10 and the shift register circuit Emit.

As shown in FIG. 1, FIG. 4 and FIG. 5, the reference voltage line Vref1 may also extend along the first direction X, and two ends of the reference voltage line Vref1 may also be cut-off ends. Therefore, further alternatively, the first signal line S1 may also be a reference voltage line Vref1 extending along the first direction X.

It should be noted that, as shown in FIG. 5, for the reference voltage line Vref1 extending along the first direction X, the reference voltage line Vref2 extending along the second direction Y may also need to be electrically connected to the reference voltage line Vref1 extending along the first direction X, and the reference voltage line Vref2 extending along the second direction Y may be electrically connected to the pixel circuit 10 through the reference voltage line Vref1 extending along the first direction X.

That is, as shown in FIG. 5, the display panel may also include a second signal line S2, the second signal line S2 may extend along the second direction Y, the first signal line S1 and the second signal line S2 may be electrically connected, and the second signal line S2 may be electrically connected to the pixel circuit 10 through the first signal line S1 to provide a signal to the pixel circuit 10. For example, the first signal line S1 may be the reference voltage line Vref1 extending in the first direction X, and the second signal line S2 may be the reference voltage line Vref2 extending in the second direction Y.

The signal line including the first signal line S1 and the second signal line S2 may be referred to as a direct driving signal line, and the first signal line S1 may also be a portion of the direct driving signal line extending along the first direction X. It should be noted that the direct driving signal line is not limited to the reference voltage line. For example, the light-emitting control signal line Emit may also be set as a direct driving signal line.

Through the above analysis, it may be understood that, as shown in FIG. 1 and FIG. 4, the display area AA of the display panel may include a first area A1 and a second area A2. The first area A1 may be located on a side of the second area A2 close to the edge of the display panel. For example, the first area A1 may be located on a side of the second area A2 close to the edge of the display panel along the first direction X. The second area A2 may

include a pixel circuit 10. The second area A2 may also include at least one driving circuit 30. The first signal line S1 may extend along the first direction X. The first signal line S1 may include a first line segment D1 and a second line segment D2 connected to each other. The

second line segment D2 of the first signal line S1 may be located in the second area A2, and the first line segment D1 of the first signal line S1 may be located in the first area A1. In the first signal line S1, the end of the first line segment D1 away from the second line segment D2 may be the cut-off end, and the cut-off end of the first line segment D1 may be the cut-off end of the first signal line S1. Therefore, electrostatic charge may be accumulated through the cut-off end of the first line segment D1 located in the edge area of the display panel, to prevent static electricity from damaging the components in the edge area close to the display panel and perform reliable electrostatic protection in the display panel.

The ability of the cut-off end of the first signal line S1 to accumulate electrostatic charge may be relatively limited. The cut-off end of the first signal line S1 may be in a long-line cut-off state, and the carrying capacity of the electrostatic charge may be relatively large. When the cut-off end of the first signal line S1 is electrostatically released, it may be possible to cause electrostatic damage to the transistor devices in the pixel circuits 10 close to the edge of the display panel along the first direction X (for example, the transistor devices in the pixel circuits 10 on the leftmost and rightmost sides of FIG. 1 and FIG. 4), and these transistor devices may be susceptible to threshold shift or characteristic failure under the influence of static electricity, which may cause abnormal display of the corresponding pixels.

Also, the ability of the cut-off end of the first signal line S1 to accumulate electrostatic charge may be improved to protect the transistor devices in the pixel circuits 10 close to the edge of the display panel along the first direction X from electrostatic damage and improve the reliability of electrostatic protection of the cut-off end of the first signal line S1.

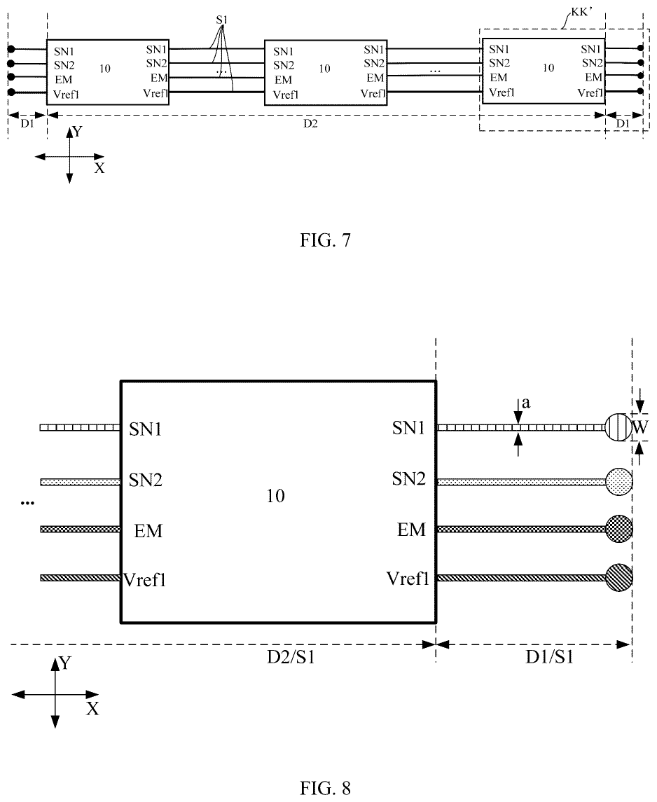

Optionally, in some embodiments shown in FIG. 7 which is a partial top view schematic diagram of another display panel, in a direction perpendicular to the extension direction of the first signal line S1 (such as the second direction Y in FIG. 7), the width of the cut-off end of the first signal line S1 may be larger than the width of other portions of the first signal line S1 except the cut-off end. In other words, by increasing the width of the cut-off end of the first signal line S1 in the direction perpendicular to the extension direction of the first signal line S1, the ability of the cut-off end of the first signal line S1 to accumulate electrostatic charge may be improved.

As shown in FIG. 7, in one embodiment, the cut-off end of the first signal line S1 may be in an arc shape. With such a setting, the cut-off end of the first signal line D1 may be relatively smooth, which may reduce the tip discharge and further improve the ability of the cut-off end of the first signal line S1 to accumulate electrostatic charge.

In one embodiment shown in FIG. 8 which is an enlarged schematic diagram of the KK′ region in FIG. 7, in the direction perpendicular to the extension direction of the first signal line S1 (such as the second direction Y in FIG. 8), the width W of the cut-off end of the first signal line S1 and the width a of the other portions of the first signal line S1 except the cut-off end may satisfy: W≥2a. With such a setting, the ability of the cut-off end of the first signal line S1 to accumulate electrostatic charge may be further improved.

In addition to increasing the width of the cut-off end of the first signal line S1 in the direction perpendicular to the extension direction of the first signal line S1 to improve the ability of the cut-off end of the first signal line S1 to accumulate electrostatic charge, the cut-off end of the first signal line S1 may also be designed as a divergent structure.

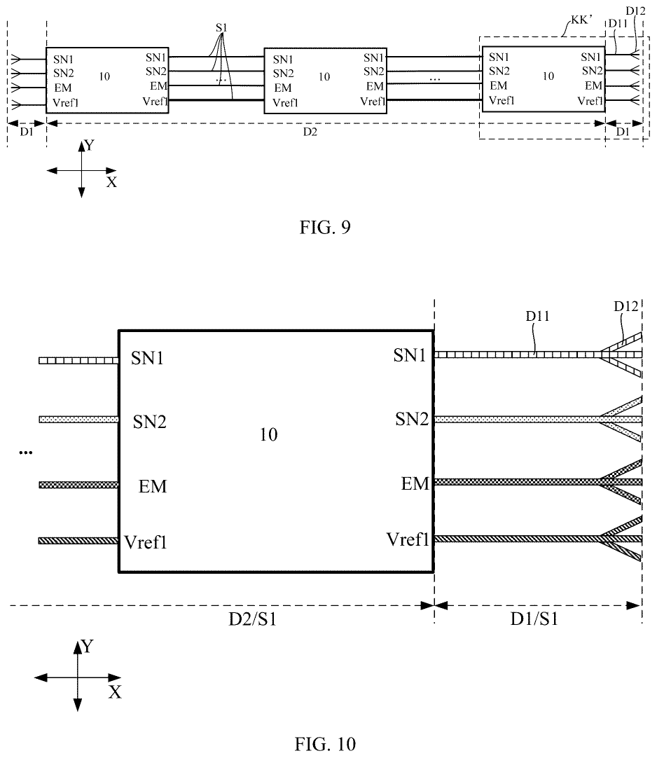

In one embodiment shown in FIG. 9 which is a partial top view schematic diagram of another display panel and FIG10 further showing an enlarged schematic diagram of the KK′ region in FIG. 9, in the first signal line S1, the first line segment D1 may include a main body D11 and a bifurcated portion D12 extending in different directions. The bifurcated portion D12 may be connected to the main body D11, and the main body D11 may be connected to the second line segment D2. In this way, the cut-off end of the first signal line S1 may be a plurality of bifurcated structures, which may increase the path for the cut-off end of the first signal line S1 to accumulate electrostatic charges, thereby improving the ability of the cut-off end of the first signal line S1 to accumulate electrostatic charges.

Comparing FIG. 8 and FIG. 10, it may be understood that, compared with designing the cut-off end of the first signal line S1 as a plurality of bifurcated structures, designing the cut-off end of the first signal line S1 as an arc shape may make the cut-off end of the first signal line S1 occupy a smaller space.

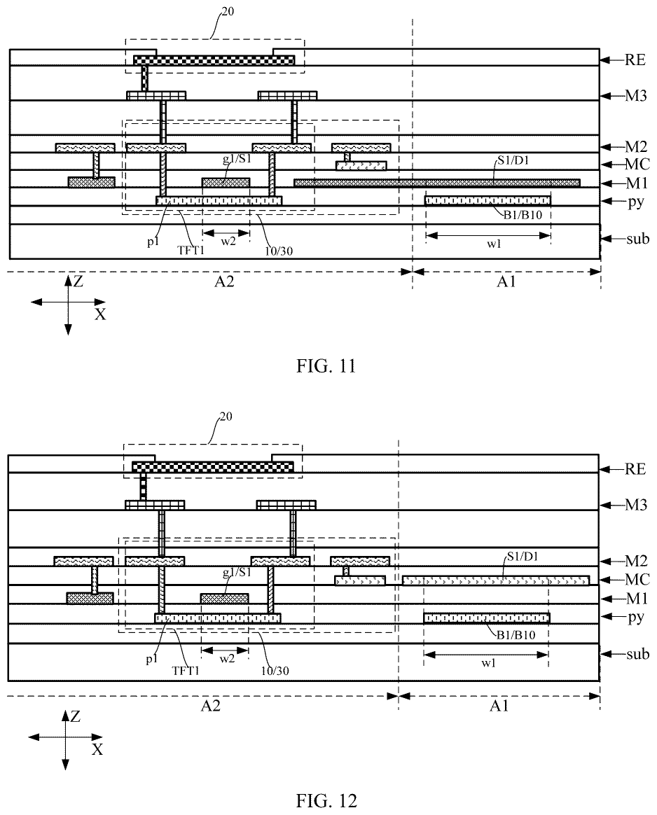

In one embodiment shown in FIG. 11 which is a schematic diagram of a partial cross-sectional structure of a display panel and FIG. 12 which is a schematic diagram of a partial cross-sectional structure of another display panel, the display panel may include a substrate sub, an active layer py located on one side of the substrate sub, and a multi-layer metal layer located on the side of the active layer py away from the substrate sub. The multi-layer metal layer may include a metal layer M1, a metal layer MC, a metal layer M2, a metal layer M3, and a metal layer RE arranged in a direction away from the substrate sub. Different metal layers, and the metal layer and the active layer may be isolated by insulating layers.

As shown in FIG. 11 and FIG. 12, the pixel circuits 10 and the driving circuits 30 may be located on the substrate sub, mainly distributed in the active layer py and some metal layers (such as the metal layer M1, metal layer MC and metal layer M2). The signal lines electrically connected to the pixel circuits 10 such as the scanning signal lines SN1, scanning signal lines SN2 and the reference voltage signal lines Vref1 may be located in some metal layers (such as the metal layer M1 and metal layer MC). The light-emitting elements 20 may be located on the side of the pixel circuits 10 away from the substrate sub, and the pixel circuits 10 may drive the light-emitting elements 20 to emit light.

As shown in FIG. 11 and FIG. 12, the first signal line S1 may be located in a metal layer among the multiple metal layers.

As known from the foregoing, the first signal line S1 may be a functional signal line electrically connecting the driving circuit 30 and the corresponding pixel circuit 10. For example, the first signal line S1 may be a scanning signal line SN1, a scanning signal line SN2 or a light-emitting control signal line EM. Optionally, as shown in FIG. 11, the first signal line S1 may be located in the metal layer M1.

As known from the foregoing, the first signal line S1 may also be a portion of the direct driving signal line extending along the first direction X. For example, the first signal line S1 may be a reference voltage line Vref1 extending along the first direction X. Optionally, as shown in FIG. 12, the first signal line S1 may be located in the metal layer MC.

In the display panel, the signal lines extending along the first direction X may be mostly located in the metal layer M1 or the metal layer MC. When the metal layer M1 or the metal layer MC is prepared, since the upper metal layer is not formed, the cut-off end of the first signal line S1 extending along the first direction X located in the metal layer M1 or the metal layer MC may be likely to carry a large amount of static electricity, which is likely to cause electrostatic damage to the pixel circuit 10 near the edge of the display panel along the first direction X.

In addition to increasing the width of the cut-off end of the first signal line S1 in the direction perpendicular to the extension direction of the first signal line S1 and designing the cut-off end of the first signal line S1 as a divergent structure to improve the ability of the cut-off end of the first signal line S1 to accumulate electrostatic charges, in the second aspect, a sacrificial structure for releasing static electricity may be set at the cut-off end of the first signal line S1. Therefore, the static electricity is preferentially released at the sacrificial structure when the electrostatic charge accumulated at the cut-off end of the first signal line S1 is too much, thereby protecting the transistor devices in the pixel circuit 10 near the edge of the display panel along the first direction X from electrostatic damage, and improving the reliability of electrostatic protection at the cut-off end of the first signal line S1.

Optionally, in some embodiments of the present disclosure, as shown in FIG. 11 and FIG. 12, the display panel may further include a first conductive portion B1, and the first conductive portion B1 and the first signal line S1 may be arranged in different layers. In a direction Z perpendicular to the plane where the display panel is located, the first conductive portion B1 and the first line segment D1 in the first signal line S1 may at least partially overlap, and an insulating layer may be disposed between the first conductive portion B1 and the first line segment D1 in the first signal line S1. With such a configuration, when too much electrostatic charge is accumulated at the cut-off end of the first signal line S1, the insulating layer between the first conductive portion B1 and the first line segment D1 in the first signal line S1 may be broken down, and the electrostatic charge may be discharged to the first conductive portion B1.

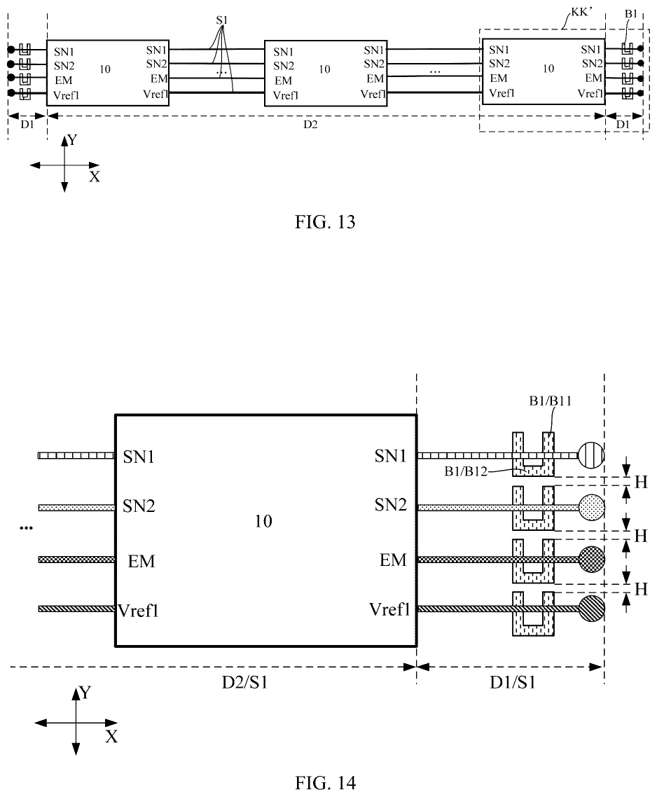

In some embodiments shown in FIG. 13 which illustrates a partial top view schematic diagram of another display panel and FIG. 14 which is an enlarged schematic diagram of the KK′ area in FIG. 13, in the direction perpendicular to the plane where the display panel is located, the cut-off end of the first signal line S1 may not overlap with the first conductive portion B1. In the direction perpendicular to the plane where the display panel is located, the first conductive portion B1 may at least partially overlap with the first line segment D1 in the first signal line S1, and the cut-off end of the first signal line S1 (that is, the cut-off end of the first line segment D1) may not overlap with the first conductive portion B1. That is, the first conductive portion B1 may be located on the inner side of the cut-off end of the first signal line S1, and the first conductive portion B1 may be located on the side of the pixel circuit 10 close to the edge of the cut-off end of the first signal line S1. Therefore, when too much electrostatic charge is accumulated at the cut-off end of the first signal line S1 and may be discharged toward the pixel circuit 10 close to the edge, the electrostatic charge may be discharged to the first conductive portion B1 first, which may more effectively protect the transistor devices in the pixel circuit 10 close to the edge of the display panel along the first direction X from electrostatic damage. Further, in the direction perpendicular to the plane where the display panel is located, the cut-off end of the first signal line S1 may not overlap with the first conductive portion B1, and the ability of the cut-off end of the first signal line S1 to accumulate electrostatic charge may be fully utilized. That is to say, such a configuration may make the cut-off end of the first signal line S1 accumulate enough electrostatic charge within the electrostatic bearing range, and then release the electrostatic charge to the first conductive portion B1, further improving the reliability of electrostatic protection of the cut-off end of the first signal line S1.

Optionally, in some other embodiments, in the direction perpendicular to the plane where the display panel is located, the cut-off end of the first signal line S1 may also overlap with the first conductive portion B1 at least partially, such that the charge may also be electrostatically released to the first conductive portion B1 after the electrostatic charge accumulated at the cut-off end of the first signal line S1 exceeds a certain degree, thereby protecting the transistor devices in the pixel circuit 10 close to the edge of the display panel along the first direction X from electrostatic damage, and improving the reliability of electrostatic protection of the cut-off end of the first signal line S1.

Optionally, in some embodiments, as shown in FIG. 11 and FIG. 12, the first conductive portion B1 may be located between the metal layer where the first signal line S1 is located and the base substrate sub. In this way, the first conductive portion B1 may be first formed on the base substrate sub, and then the first signal line S1 may be formed on the side of the first conductive portion B1 away from the base substrate sub, such that the charge may be released to the first conductive portion B1 when a large amount of electrostatic charge is accumulated at the cut-off end of the first signal line S1 during the preparation of the metal layer where the first signal line S1 is located, thereby improving the preparation yield of the display panel. Also, during the use of the display panel, the electrostatic charge accumulated at the cut-off end of the first signal line S1 may also be released to the first conductive portion B1.

Optionally, in some other embodiments, the first conductive portion B1 may also be located on a side of the metal layer where the first signal line S1 is located away from the substrate sub. In this way, during the use of the display panel, the electrostatic charge accumulated at the cut-off end of the first signal line S1 may be released to the first conductive portion B1.

On the basis that the first conductive portion B1 may be located between the metal layer where the first signal line S1 is located and the substrate sub, considering that the first signal line S1 may be located in the metal layer M1 or the metal layer MC, optionally, in some embodiments, as shown in FIG. 11 and FIG. 12, the first conductive portion B1 may be located in the active layer py.

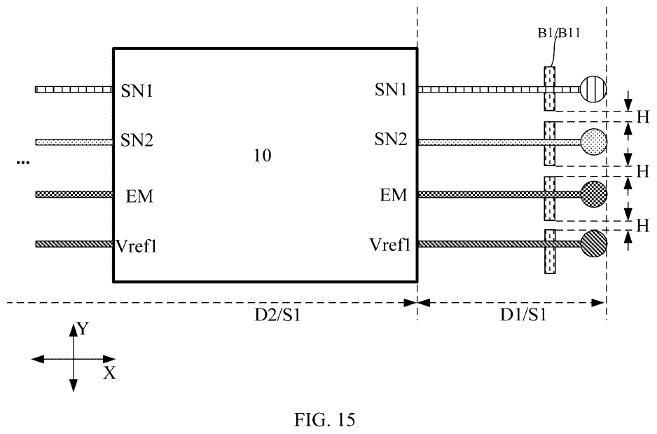

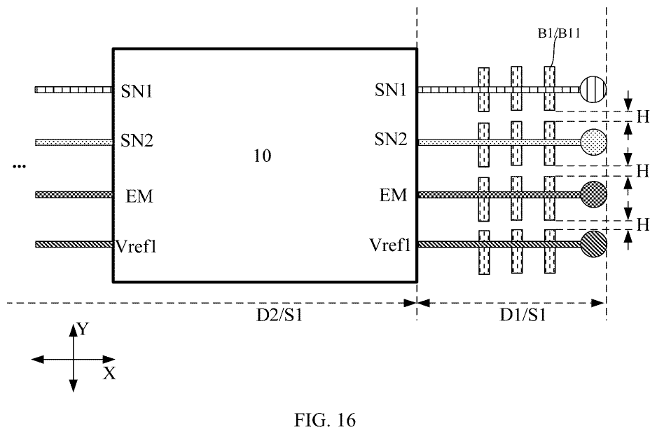

In one embodiment shown in FIG. 15 which is an enlarged schematic diagram of a local edge area of a display panel along the first direction X, the first conductive portion B1 may include at least one first sub-conductive portion B11, and the first sub-conductive portion B11 may extend along the second direction Y. In the direction perpendicular to the plane where the display panel is located, the first sub-conductive portion B11 may overlap with the first line segment D1.

It may be understood that, when the first line segment D1 in the first signal line S1 performs electrostatic discharge to the first sub-conductive portion B11 that overlaps in the direction perpendicular to the plane where the display panel is located, the corresponding first sub-conductive portion B11 may be actually electrostatically damaged, that is, the corresponding first sub-conductive portion B11 may be used as a sacrificial structure for electrostatic discharge. Therefore, by increasing the number of first sub-conductive portions B11, the transistor devices in the pixel circuit 10 near the edge of the display panel may be further protected from electrostatic damage, thereby improving the reliability of electrostatic protection at the cut-off end of the first signal line S1.

In one embodiment in FIG. 16 which shows an enlarged schematic diagram of a local edge area of another display panel provided in an embodiment of the present application along the first direction X, the first conductive portion B1 may include at least two first sub-conductive portions B11, and the first sub-conductive portions B11 may be arranged along the first direction X. For example, in one embodiment, the first conductive portion B1 in FIG. 16 may include three first sub-conductive portions B11, and the three first sub-conductive portions B11 may be arranged along the first direction X. In this way, when the cut-off end of the first signal line S1 accumulates a large amount of electrostatic charge, the electrostatic charge may be discharged to the first sub-conductive portions B11 arranged along the first direction X in sequence, to further protect the transistor devices in the pixel circuit 10 close to the edge of the display panel along the first direction X from electrostatic damage and improve the reliability of electrostatic protection of the cut-off end of the first signal line S1.

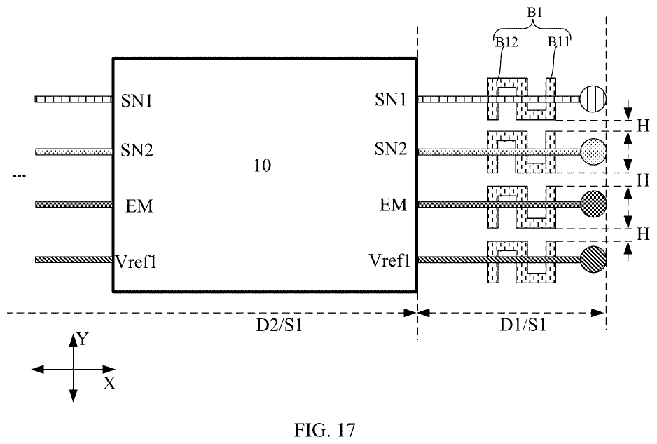

On the basis that the first conductive portion B1 includes at least two first sub-conductive portions B11 arranged along the first direction X, as shown in FIG. 14 and FIG. 17 which is an enlarged schematic diagram of a local edge area of another display panel along the first direction X, the first conductive portion B1 may also include a second sub-conductive portion B12 connecting two adjacent first sub-conductive portions B11, and the second sub-conductive portion B12 may extend along the first direction X.

Optionally, as shown in FIG. 14, the first conductive portion B1 may include two first sub-conductive portions B11 and a second sub-conductive portion B12 connecting the two first sub-conductive portions B11, such that the first conductive portion B1 is U-shaped.

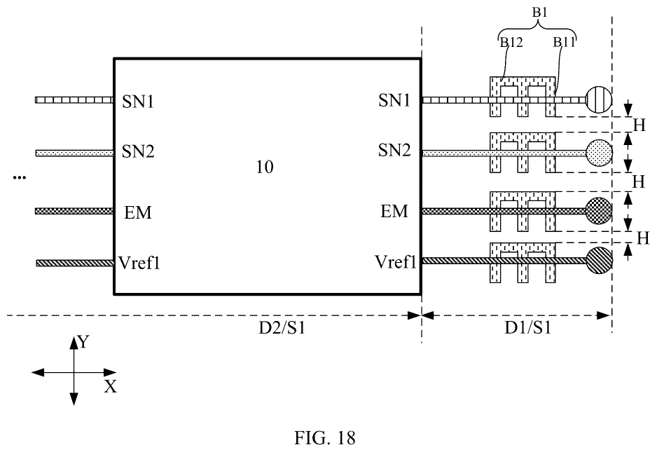

Alternatively, as shown in FIG. 17, the first conductive portion B1 may include three first sub-conductive portions B11 and two second sub-conductive portions B12 connecting any two adjacent first sub-conductive portions B11, such that the first conductive portion B1 is S-shaped. In addition, as shown in FIG. 18 which is an enlarged schematic diagram of a local edge area of another display panel along the first direction X, when the first conductive portion B1 includes three first sub-conductive portions B11 and two second sub-conductive portions B12 connecting two adjacent first sub-conductive portions B11, the first conductive portion B1 may also be M-shaped.

In some other embodiments, the first conductive portion B1 may also include more than three first sub-conductive portions B11 and multiple second sub-conductive portions B12 connecting two adjacent first sub-conductive portions B11, and the first conductive portion B1 may be in other suitable shapes.

From the above analysis, it may be seen that the second area A2 of the display panel (the middle area of the display area AA) may include pixel circuits 10 and at least one driving circuit 30. The pixel circuits 10 and the driving circuits 30 may both include multiple thin film transistors, that is, the second area A2 of the display panel may include multiple thin film transistors. As shown in FIG. 11 and FIG. 12, the multiple thin film transistors may include a first transistor TFT1. The first transistor TFT1 may be a thin film transistor in the pixel circuit 10 or a thin film transistor in the driving circuit 30. The first transistor TFT1 may include a channel region p1 located in the active layer py. In the direction Z perpendicular to the plane where the display panel is located, the channel region p1 of the first transistor TFT1 may overlap with the first signal line S1. The portion of the first signal line S1 overlapping with the channel region p1 of the first transistor TFT1 may be the gate g1 of the first transistor TFT1.

As shown in FIG. 11 and FIG. 12, along the extension direction of the first signal line S1, that is, along the first direction X, the width w1 of the first sub-conductive portion B11 overlapping with the first signal line S1 in the direction Z perpendicular to the plane where the display panel is located may be larger than the width w2 of the channel region p1 of the first transistor TFT1 overlapping with the first signal line S1 in the direction Z perpendicular to the plane where the display panel is located, that is, w1>w2. In this way, when a large amount of electrostatic charge accumulates at the cut-off end of the first signal line S1, the charge may be preferentially released to the first sub-conductive portions B11, and may not be preferentially released to the first transistor TFT1 close to the edge of the display panel along the first direction X, to better protect the first transistor TFT1 close to the edge of the display panel along the first direction X from electrostatic damage, and improve the reliability of electrostatic protection at the cut-off end of the first signal line S1.

In practical applications, the width w2 of the channel region p1 of the first transistor TFT1 overlapping with the first signal line S1 in the direction Z perpendicular to the plane where the display panel is located may be less than or equal to 4 μm. In this case, the width w1 of the first sub-conductive portion B11 overlapping with the first signal line S1 in the direction Z perpendicular to the plane where the display panel is located may be set to be greater than or equal to 4 μm.

Optionally, in some embodiments, the shape of the first conductive portion B1 may be the same as the shape of the channel region p1 of the first transistor TFT1 closest to the first conductive portion B1 along the extension direction of the first signal line S1 (i.e., along the first direction X). For example, the shape of the channel region p1 of the first transistor TFT1 closest to the first conductive portion B1 along the extension direction of the first signal line S1 (i.e., along the first direction X) may be a rectangle, and the shape of the first conductive portion B1 may be a rectangle.

Optionally, in other embodiments, the shape of the first conductive portion B1 may be different from the shape of the channel region p1 of the first transistor TFT1 closest to the first conductive portion B1 along the extension direction of the first signal line S1 (i.e., along the first direction X).

For example, as shown in FIG. 7 to FIG. 10 and FIG. 13 to FIG. 18, the first signal line S1 may include multiple types of first signal lines, and the multiple types of first signal lines may include scan signal lines SN1, scan signal lines SN2, and reference voltage signal lines Vref1. The first conductive portions B1 of different types of first signal lines S1 that overlap in the direction perpendicular to the plane where the display panel is located may have the same shape. Thus, when preparing the first conductive portions B1 of different types of first signal lines S1 that overlap in the direction perpendicular to the plane where the display panel is located, the same mask pattern may be used to simplify the layout design of the display panel. Moreover, as long as the shape design of the first conductive portion B1 is sufficient to protect the transistor devices near the edge of the display panel along the first direction X from electrostatic damage, it may be fine.

As shown in FIG. 14 to FIG. 18, the first signal line S1 may include multiple types of first signal lines, for example, a scanning signal line SN1, a scanning signal line SN2, a light-emitting control signal line EM and a reference voltage line Vref1. The different types of first signal lines S1 may be arranged along the second direction Y. Along the second direction Y, a distance H between the first conductive portions B1 that overlap with two adjacent types of first signal lines S1 in the direction perpendicular to the plane where the display panel is located may satisfy: H≥5 μm. In this way, electrostatic breakdown may be prevented between the first conductive portions B1 that overlap with two adjacent types of first signal lines S1 in the direction perpendicular to the plane where the display panel is located along the second direction Y.

In the above-mentioned embodiments, the circuit structure of the pixel circuit 10 is mainly described by taking the circuit structure of 7T1C shown in FIG. 6 as an example. In this case, the first signal line S1 may be a scanning signal line SN1, a scanning signal line SN2, a light-emitting control signal line EM, or a reference voltage line Vref1.

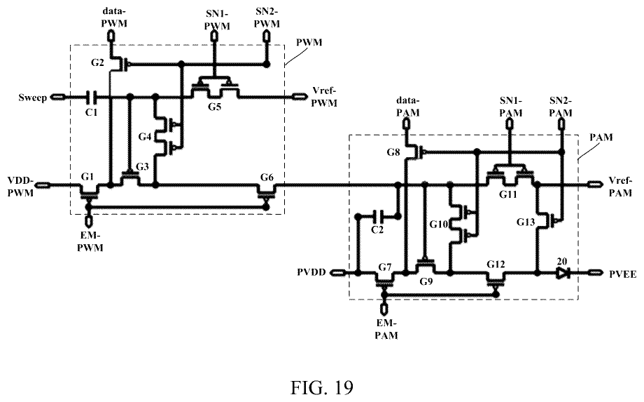

In some other embodiment shown in FIG. 19 which is a schematic diagram of the circuit structure of another pixel circuit 10, the pixel circuit 10 may also be a 13T2C structure, and may include a pulse width module PWM controlled by pulse width modulation and an amplitude module PAM controlled by pulse amplitude modulation, to achieve the best performance of the light-emitting efficiency and viewing angle color deviation of the driven light-emitting element 20 (such as a light-emitting diode). The pulse width module PWM in the pixel circuit 10 may include six thin film transistors (G1-G6) and a capacitor (C1), and the signal lines electrically connected to the pulse width module PWM may include a scanning signal line SN1-PWM, a scanning signal line SN2-PWM, a light-emitting control signal line EM-PWM, a reference voltage signal line Vref-PWM, a data signal line data-PWM, a shutdown voltage signal line VDD-PWM, and a pulse width control voltage line Sweep. The pulse width module PWM may be used to control the light-emitting duration of the light-emitting element 20 (such as a light-emitting diode). The amplitude module PA in the pixel circuit 10 M may include seven thin film transistors (G7-G13) and a capacitor (C2), and the signal lines electrically connected to the amplitude module PAM may include a scanning signal line SN1-PWM, a scanning signal line SN2-PWM, a light-emitting control signal line EM-PWM, a reference voltage signal line Vref-PWM, a data signal line data-PWM, and a power supply voltage line PVDD. The amplitude module PAM may be electrically connected to one electrode of the light-emitting element 20, and the other electrode of the light-emitting element 20 may be electrically connected to the power supply voltage line PVEE. The amplitude module PAM may be used to control the light intensity of the light-emitting element 20 (such as a light-emitting diode). The electrical connection relationship between the transistors in the 13T2C pixel circuit and the electrical connection relationship between the transistors and the signal lines may be as shown in FIG. 19, which will not be repeated.

It should be noted that the pixel circuit 10 shown in FIG. 19 is also only an example. In actual applications, pixel circuits with other circuit structures may be selected based on needs.

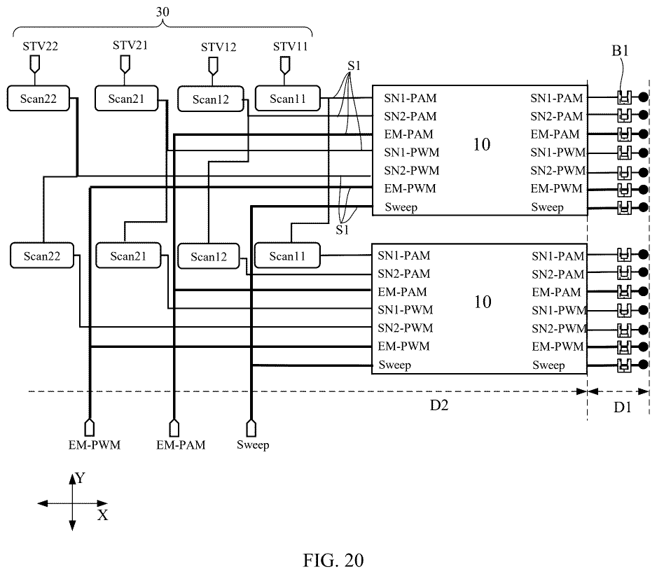

In one embodiment shown in FIG. 20 which is a schematic diagram of the electrical connection relationship of a local edge area of another display panel, the driving circuit 30 may include scanning circuits STV11, STV12, STV21 and STV22. The scanning circuit STV11 may include a multi-stage cascaded shift register circuit Scan11, and the shift register circuit Scan11 may be electrically connected to the amplitude module PAM in the pixel circuit 10 through the scanning signal line SN1-PAM extending along the first direction X. The scanning circuit STV12 may include a multi-stage cascaded shift register circuit Scan12, and the shift register circuit Sc an12 may be electrically connected to the amplitude module PAM in the pixel circuit 10 through the scanning signal line SN2-PAM extending along the first direction X. The scanning circuit STV21 may include a multi-stage cascaded shift register circuit Scan21, and the shift register circuit Scan21 may be electrically connected to the pulse width module PWM in the pixel circuit 10 through the scanning signal line SN1-PWM extending along the first direction X. The scanning circuit STV22 may include a multi-stage cascaded shift register circuit Scan22, and the shift register circuit Scan22 may be electrically connected to the pulse width module PWM in the pixel circuit 10 through the scanning signal line SN2-PWM extending along the first direction X.

As shown in FIG. 20, the display panel may further include light-emitting control signal lines EM-PWN, EM-PAN and a pulse width control voltage line Sweep. The light-emitting control signal lines EM-PWN, EM-PAN and the pulse width control voltage line Sweep may all be direct driving signal lines, including a portion extending along the first direction X.

As shown in FIG. 20, the first signal line S1 may be a functional signal line electrically connected to the driving circuit 30 and the pixel circuit 10, or may be a portion of the direct driving signal line extending along the first direction X. For example, the first signal line S1 may be a scanning signal line SN1-PWM, a scanning signal line SN2-PWM, or a portion of the light-emitting control signal line EM-PWM and the pulse width control voltage line Sweep electrically connected to the pulse width module PWM. The first signal line S1 may also be a portion of the scanning signal line SN1-PAM, a scanning signal line SN2-PAM and a light-emitting control signal line EM-PWN electrically connected to the amplitude module PAM along the first direction X. The designs of widening the cut-off end of the first signal line S1 or designing it as a divergent structure and overlapping the first conductive portion B1 in the direction perpendicular to the plane of the display panel introduced in the above-mentioned embodiments may be still all applicable and will not be repeated.

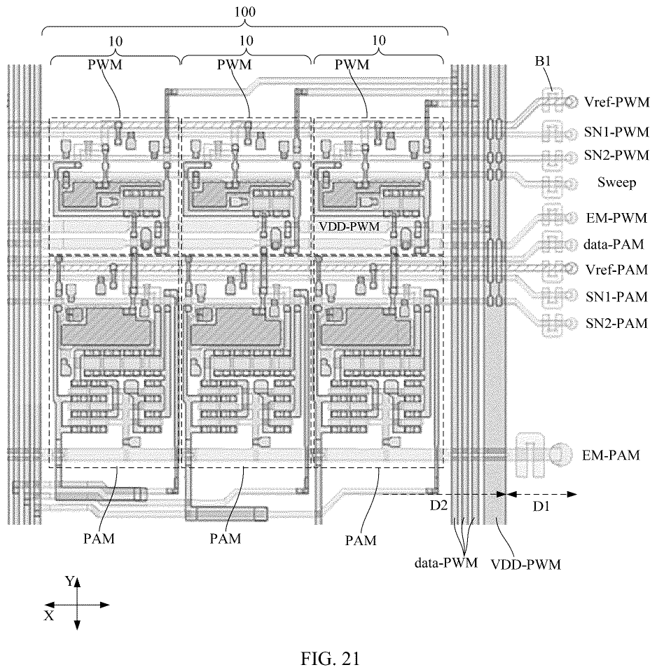

In another embodiment shown in FIG. 21 which is a schematic diagram of the layout structure of a local edge area of another display panel along the first direction X, FIG. 21 shows a group of pixel circuit groups 100, and the pixel circuit group 100 may include three pixel circuits 10 arranged along the first direction X. The circuit structure of the pixel circuit 10 may be as shown in FIG. 20, including a pulse width module PWM and an amplitude module PAM. The signal lines electrically connected to the pixel circuit 10 and extending along the first direction X may include a reference voltage signal line Vref-PWM, a scanning signal line SN1-PWM, a scanning signal line SN2-PWM, a pulse width control voltage line Sweep, a light-emitting control signal line EM-PWM, a data signal line data-PAM, a reference voltage signal line Vref-PAM, a scanning signal line SN1-PAM, a scanning signal line SN2-PAM, and a light-emitting control signal line EM-PAM. The reference voltage signal line Vref-PWM, scanning signal line SN1-PWM, scanning signal line SN2-PWM, pulse width control voltage line Sweep and light-emitting control signal line EM-PWM may be electrically connected to the pulse width module PWM in the pixel circuit 10, and the data signal line data-PAM, reference voltage signal line Vref-PAM, scanning signal line SN1-PAM, scanning signal line SN2-PAM and light-emitting control signal line EM-PAM may be electrically connected to the amplitude module PAM in the pixel circuit 10.

As shown in FIG. 20 and FIG. 21, the first signal lines S1 may include multiple types of first signal lines, such as reference voltage signal lines Vref-PWM, scan signal lines SN1-PWM, scan signal lines SN2-PWM, pulse width control voltage lines Sweep, light-emitting control signal lines EM-PWM, data signal lines data-PAM, reference voltage signal lines Vref-PAM, scan signal lines SN1-PAM, scan signal lines SN2-PAM and light-emitting control signal line EM-PAM. Different types of first signal lines S1 may be arranged along the second direction Y, and each type of first signal lines S1 may adopt the design introduced in the aforementioned embodiments of widening the cut-off end of the first signal line S1 or designing it as a divergent structure and overlapping the first conductive portion B1 in the first signal line segment D1 in the direction perpendicular to the plane where the display panel is located.

For example, as shown in FIG. 20 and FIG. 21, the cut-off ends of the different types of first signal lines S1 extending along the first direction X electrically connected to the pixel circuit 10 may be a widened arc shape, and the first line segments D1 of the different types of first signal lines S1 may be provided with overlapping first conductive portions B1 in the direction perpendicular to the plane where the display panel is located.

As shown in FIG. 21, the multiple types of first signal lines S1 in the display panel may include first-type first signal lines and second-type first signal lines, and the width of the first-type first signal lines along the second direction Y may be larger than the width of the second-type first signal lines along the second direction Y. The first conductive portions B1 may include first-type first conductive portions and second-type second conductive portions. In the direction perpendicular to the plane where the display panel is located, the first-type first conductive portions may overlap with the first-type first signal lines, and the second-type first conductive portions may overlap with the second-type first signal line. The area of the orthographic projection of the first-type first conductive portions perpendicular to the plane where the display panel is located may be larger than the area of the orthographic projection of the second-type first conductive portion perpendicular to the plane where the display panel is located.

For example, as shown in FIG. 21, one first-type first signal line may be a light-emitting control signal line EM-PAM extending along the first direction X, and one second-type first signal line may be a reference voltage signal line Vref-PWM, a scan signal line SN1-PWM, a scan signal line SN2-PWM, a pulse width control voltage line Sweep, a light-emitting control signal line EM-PWM, a data signal line data-PAM, a reference voltage signal line Vref-PAM, a scan signal line SN1-PAM or a scan signal line SN2-PAM extending along the first direction X. The width of the light-emitting control signal line EM-PAM along the second direction Y may be larger than the width of the second-type first signal line such as the scan signal line SN1-PAM along the second direction Y. In the direction perpendicular to the plane where the display panel is located, the area of the first conductive portion B1 overlapping with the light-emitting control signal line EM-PAM may be larger than the area of the first conductive portion B1 overlapping with the second-type first signal lines such as the scan signal line SN2-PAM.

Therefore, for the first signal line S1 with a larger width along the second direction Y, the area of the corresponding overlapping first conductive portion B1 may be larger, which may better protect the transistor devices in the pixel circuit 10 close to the edge of the display panel along the first direction X from electrostatic damage and improve the reliability of electrostatic protection of the cut-off end of the first signal line S1.

Based on a similar design idea, in some other embodiments, it may also be set that the number of first-type first conductive portions overlapping with the first-type first signal lines to be larger than the number of second-type first conductive portions overlapping with the second-type first signal lines in the direction perpendicular to the plane where the display panel is located, to better protect the transistor devices in the pixel circuit 10 close to the edge of the display panel along the first direction X from electrostatic damage and improve the reliability of electrostatic protection of the cut-off end of the first signal line S1.

Further, considering that the lines in the display panel are very dense, it may be possible to set the first conductive portions B1 of some types of first signal lines S1 overlapping in the direction perpendicular to the plane where the display panel is located and the first conductive portions B1 of other types of first signal lines S1 overlapping in the direction perpendicular to the plane where the display panel is located to be staggered along the second direction Y. For example, as shown in FIG. 21, in one embodiment, the first-type first signal lines may be the light-emitting control signal lines EM-PAM extending along a first direction X, and the second-type first signal lines may be the scanning signal lines SN2-PAM extending along the first direction X. In the direction perpendicular to the plane where the display panel is located, the first-type first conductive portions overlap with the first-type first signal lines, and the second-type first conductive portions overlap with the second-type first signal lines. Along the second direction Y, the first conductive portions B1 (i.e., the first-type first conductive portions) of the light-emitting control signal lines EM-PAM overlapping in the direction perpendicular to the plane where the display panel is located and the first conductive portions B1 (i.e., the second-type first conductive portions) of the scanning signal lines SN2-PAM overlapping in a direction perpendicular to the plane where the display panel is located may not overlap along the second direction Y.

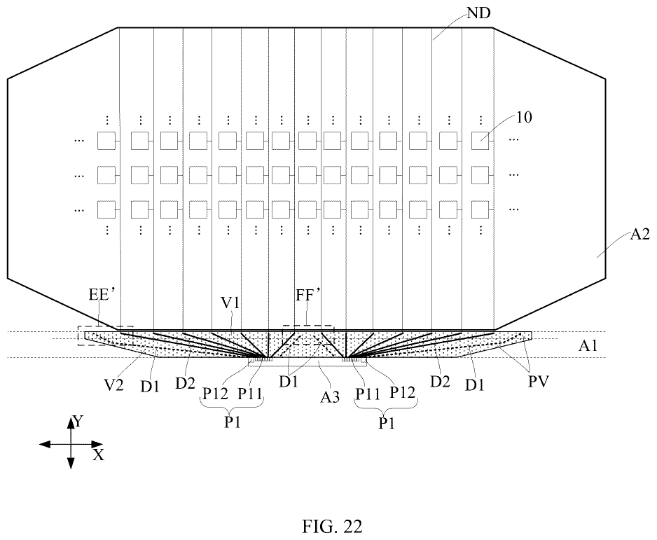

In some other embodiment shown in FIG. 22 which is a top view schematic diagram of a display panel consistent with the present disclosure, the display panel may include a first area A1 and a second area A2. The second area A2 may be a display area. The second area A2 may include pixel circuits 10, and may also include data signal lines ND arranged along a first direction X and extending along a second direction Y. One data signal line ND may be electrically connected to one corresponding pixel circuit 10, and the data signal line ND may be used to provide a data signal to the corresponding pixel circuit 10. The first direction X and the second direction Y may intersect, and the first direction X and the second direction Y may be parallel to the plane where the display panel is located.

As shown in FIG. 22, in the display panel, the first area A1 may be located on the side of the second area A2 close to the edge of the display panel. For example, the first area A1 may be located on the side of the second area A2 along the second direction Y. The first area A1 may be a fan-out area.

As shown in FIG. 22, the first area A1 may include first line segments D1 and second line segments D2. That is, the first line segments D1 and the second line segments D2 may be all located in the first area A1. The multiple second line segments D2 may be arranged along the first direction X, and the first line segments D1 may be located on at least one side of the multiple second line segments D2 along the first direction X.

As shown in FIG. 22, the display panel may also include a third area A3 located on the side of the first area A1 away from the second area A2. The third area A2 may be a pin area. The third area A3 may include a plurality of pins P1. The plurality of pins P1 may include a data pin P11. One end of one second line segment D2 may be electrically connected to one corresponding data pin P11, and the other end of the second line segment D2 may be electrically connected to the corresponding data signal line ND. That is, the second line segment D2 may be a fan-out routing, and the data pin P11 may be electrically connected to the data signal line ND through the second line segment D2 to transmit the data signal to the data signal line ND. The two ends of the second line segment D2 may be non-cut-off ends.

As shown in FIG. 22, in the first area A1, the first line segments D1 may be provided on at least one side of the multiple second line segments D2 along the first direction X, and the extension direction of the first line segments D1 may be the same as the extension direction of the second line segments D2. It should be noted that in the embodiments of the present disclosure, the extension direction of the first line segments D1 may be the same as the extension direction of the second line segments D2, which means that the first line segments D1 and the second line segments D2 may all be extended from the data pins P11 of the third area A3 to the direction of the data signal lines ND of the second area A2, and it does not limit the first line segments D1 and the second line segments D2 to be completely parallel.

As shown in FIG. 22, in the first area A1, both ends of one first line segment D1 may be cut-off ends. That is, although the first line segments D1 and the second line segments D2 extend in the same direction, the first line segments D1 may be neither electrically connected to the data pins P11 of the third area A3 nor to the data signal lines ND in the second area A2, that is, the first line segments D1 may not be used to transmit data signals, but may be used to perform electrostatic protection on the second line segments D2 that transmits data signals.

Since the first line segments D1 are located on one side of the multiple second line segments D2 and both ends of one first line segment D1 may be non-cut-off ends, static electricity in and near the first area A1 (edge area) of the display panel may be accumulated at the cut-off ends of the first line segments D1, preventing static electricity from damaging the second line segments D2 used to transmit data signals in the first area A1, that is, preventing static electricity from damaging the components near the edge area of the display panel and performing reliable electrostatic protection in the display panel.

The ability of the cut-off ends of the first line segments D1 to accumulate electrostatic charge is relatively limited. As shown in FIG. 22, the display panel may include a first power voltage line PV, and the plurality of pins P1 in the third area A3 may include a first power pin P12, and the first power pin P12 may be electrically connected to the first power voltage line PV.

The first power supply voltage line PV may be a power supply voltage line PVDD. Thus, referring to the pixel circuit 10 shown in FIG. 6 and FIG. 19, the first power supply voltage line PV may be also electrically connected to the pixel circuit 10 in the second area A2, and the first power supply voltage line PV may be used to provide the first power supply voltage signal to the pixel circuit 10.

Alternatively, the first power supply voltage line PV may also be a power supply voltage line PVEE. Thus, as shown in FIG. 6 and FIG. 19, the first power supply voltage line PV may also be electrically connected to the light-emitting element in the second area A2.

The first power supply voltage line PV may include a first subordinate line located in the second area A2. The first subordinate line may be electrically connected to the pixel circuit 10 or to the light-emitting element. The first subordinate lines may be arranged in a grid in the second area A2, or may be arranged on the entire surface, depending on the specific situation.

As shown in FIG. 22, the first power supply voltage line PV may also include a first main body V1 and a first extension portion V2 located in the first area A1. The first main body portion V1 may extend along the first direction X such that the first main body portion V1 is electrically connected to the first subordinate line of the second area A2. The first main body V1 may be electrically connected to the first extension portion V2, and the first extension portion V2 may be electrically connected to the first power pin P12. The first extension portion V2 may be fanned out from the first power pin P12 to the first main body V1, which may be an overall fan-out or a strip fan-out, depending on the specific situation.

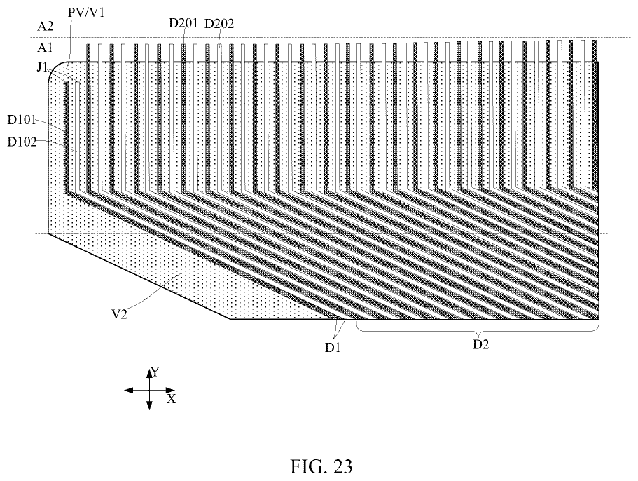

For better understanding, FIG. 23 shows an enlarged schematic diagram of the layout structure of the EE′ area in FIG. 22. As shown in FIG. 23, one or more (such as two) first line segments D1 may be set on both sides of the multiple second line segments D2 (i.e., fan-out wiring) along the first direction X, for electrostatic protection of the second line segments D2 transmitting the data signal.

As shown in FIG. 22 and FIG. 23, the first main body V1 of the first power supply voltage line PV and the second line segment D2 may be arranged in different layers, and in the direction perpendicular to the plane where the display panel is located, the first main body V1 and the second line segment D2 may at least partially overlap. The first main body V1 of the first power supply voltage line PV and the first line segment D1 may be arranged in different layers, and in the direction perpendicular to the plane where the display panel is located, the first main body V1 and the first line segment D1 may at least partially overlap.

As shown in FIG. 22 and FIG. 23, in the direction perpendicular to the plane where the display panel is located, the cut-off end J1 of the first line segment D1 close to the second area A2 may be covered by the first main body V1. Therefore, when the second line segment D2 of the first area A1 is subjected to static electricity, the cut-off end J1 of the first line segment D1 close to the second area A2 may accumulate static electricity. Once the static electricity accumulated at the cut-off end J1 of the first line segment D1 close to the second area A2 is released, a tip discharge occurs, which is likely to damage the first main body V1 of the first power supply voltage line PV, destroy the transmission of the first power supply voltage line PV, and even cause a short circuit.

As shown in FIG. 23, the metal layer where the first main body V1 and the first extension portion V2 of the first power supply voltage line PV are located may be located above the metal layer where the first line segment D1 and the second line segment D2 are located. To show the first line segment D1 and the second line segment D2, the first line segment D1 and the second line segment D2 are drawn above the first main body V1 and the first extension portion V2 of the first power supply voltage line PV.

As shown in FIG. 22, since the driving integrated circuit IC in the display panel does not match the screen resolution, two groups of left and right second line segments D2 arranged along the first direction X may be set in the first area A1, and each group of second line segments D2 may include multiple second line segments D2. One or more first line segments D1 may be set on two sides of each group of second line segments D2 along the first direction X to perform electrostatic protection on the second line segments D2 in the group of second line segments D2, and the two sides of one group of second line segments D2 on the left side along the first direction X may correspond to the EE′ area and the FF″ area respectively.

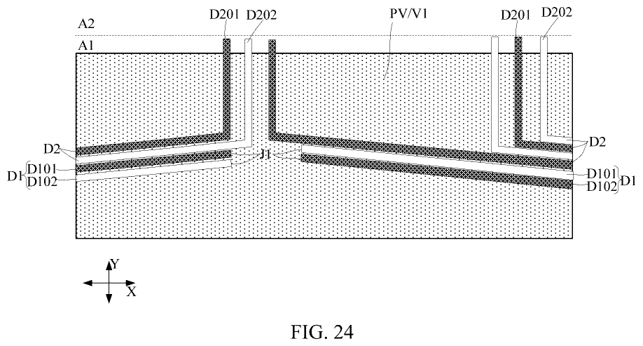

It can be understood that, as shown in FIG. 24 which is an enlarged schematic diagram of the layout structure of the FF′ area in FIG. 22, in the direction perpendicular to the plane where the display panel is located, the cut-off end J1 of the first line segment D1 close to the second area A2 may be covered by the first main body V1. When the second line segment D2 of the first area A1 is subjected to static electricity, the cut-off end J1 of the first line segment D1 close to the second area A2 may accumulate static electricity. Once the static electricity accumulated by the cut-off end J1 of the first line segment D1 close to the second area A2 is released, tip discharge occurs, which is likely to damage the first main body V1 of the first power supply voltage line PV and destroy the transmission of the first power supply voltage line PV. In FIG. 24, to show the first line segment D1 and the second line segment D2, the first line segment D1 and the second line segment D2 are drawn above the first main body V1 and the first extension portion V2 of the first power supply voltage line PV. Similar situations are not repeated below.

The cut-off end J1 of the first line segment D1 close to the second area A2 may be extended out of the area outside the first main body V1 to form a protruding structure. In this way, even when the cut-off end J1 of the first line segment D1 close to the second area A2 accumulates a lot of electrostatic charge for tip discharge, it may not cause damage to the first main body V1 of the nearby first power line PVDD.

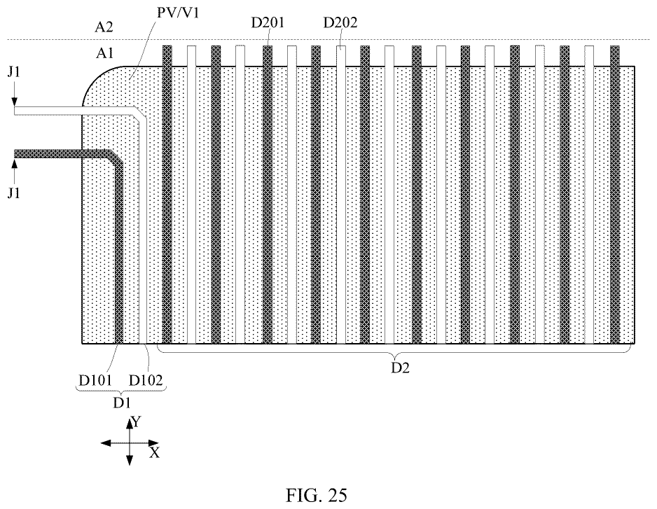

For example, as shown in FIG. 25 which is another enlarged schematic diagram of the layout structure corresponding to the EE′ area in FIG. 22, compared with FIG. 23, it can be seen that in the layout structure shown in FIG. 25, the cut-off end J1 of the first line segment D1 close to the second area A2 may be extended out of the area outside the first main body V1 to form a protruding structure, such that in the direction perpendicular to the plane where the display panel is located, the cut-off end J1 of the first line segment D1 close to the second area A2 does not overlap with the first main body V1 of the first power voltage line PV, to avoid the electrostatic charge accumulated at the cut-off end J1 of the first line segment D1 close to the second area A2 from damaging the first main body V1 of the first power line PVDD when the discharge is performed.

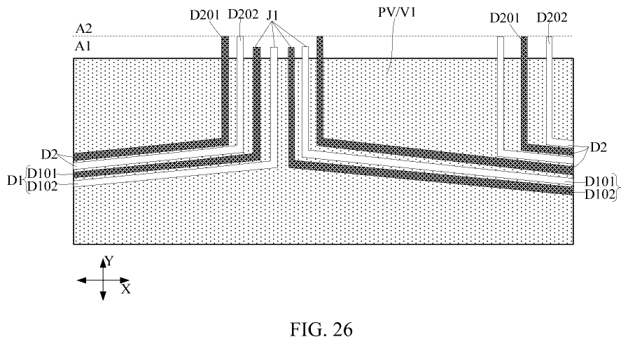

As shown in FIG. 26 which is another enlarged schematic diagram of the layout structure corresponding to the FF′ area in FIG. 22, compared with FIG. 24, in the layout structure shown in FIG. 26, by extending the cut-off end J1 of the first line segment D1 close to the second area A2 out of the area outside the first main body V1, a protruding structure may be formed. Therefore, in the direction perpendicular to the plane where the display panel is located, the cut-off end J1 of the first line segment D1 close to the second area A2 may not overlap with the first main body V1 of the first power supply voltage line PV, to avoid the electrostatic charge accumulated at the cut-off end J1 of the first line segment D1 close to the second area A2 from damaging the first main body V1 of the first power supply line PVDD when it is released.

Also, the ability of the cut-off end J1 of the first line segment D1 close to the second area A2 to accumulate electrostatic charge may be improved by increasing the width of the cut-off end J1 of the first line segment D1 close to the second area A2 in the direction perpendicular to the extension direction of the first line segment D1, and designing the cut-off end of the first line segment D1 as a divergent structure.

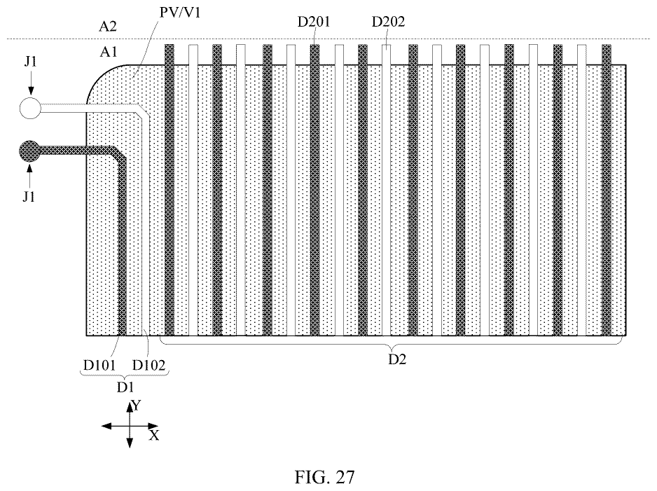

FIG. 27 shows another enlarged schematic diagram of the layout structure corresponding to the EE′ region in FIG. 22. As shown in FIG. 27, in the direction perpendicular to the extension direction of the first line segment D1, the width of the cut-off end of the first line segment D1 close to the second area A2 may be larger than the width of the other portions of the first line segment D1 except the cut-off end. For example, on the basis of extending the cut-off end J1 of the first line segment D1 close to the second area A2 out of the first main body V1 to form a protruding structure, the cut-off end J1 of the first line segment D1 close to the second area A2 may be further arranged to be in an arc shape. Such an arrangement may not only prevent the electrostatic charge accumulated at the cut-off end J1 of the first line segment D1 close to the second area A2 from damaging the first main body V1 when releasing, but also improve the ability of the cut-off end J1 of the first line segment D1 close to the second area A2 to accumulate electrostatic charge, to improve the reliability of electrostatic protection of the cut-off end of the first line segment D1.

FIG. 27 shows that the width of the cut-off end J1 of the first line segment D1 near the second area A2 may be increased on the basis that the cut-off end J1 of the first line segment D1 near the second area A2 extends out of the first main body V1 to form a protruding structure. It may be understood that, even when the cut-off end J1 of the first line segment D1 near the second area A2 may not be extended out of the first main body V1 to form a protruding structure and only the width of the cut-off end J1 of the first line segment D1 near the second area A2 may be increased, the ability of the cut-off end J1 of the first line segment D1 near the second area A2 to accumulate electrostatic charge may be improved, thereby preventing the cut-off end J1 of the first line segment D1 near the second area A2 from releasing static electricity to damage the first main body V1 of the first power line PVDD to a certain extent.

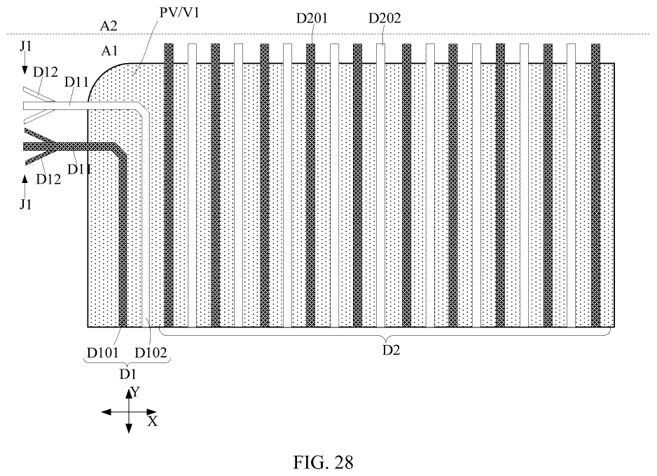

FIG. 28 shows another enlarged schematic diagram of the layout structure corresponding to the EE′ area in FIG. 22. As shown in FIG. 28, the first line segment D1 may include a main body D11 and forked portions D12 extending in different directions, and the forked portions D12 may be connected to the main body D11. In this way, the cut-off end of the first line segment D1 close to the second area A2 may be a bifurcated structure to increase the path for the cut-off end of the first line segment D1 close to the second area A2 to accumulate electrostatic charge, thereby improving the ability of the cut-off end of the first line segment D1 close to the second area A2 to accumulate electrostatic charge.

FIG. 28 shows that, on the basis of the cut-off end J1 of the first line segment D1 close to the second area A2 extending out of the first main body V1 to form a protruding structure, the cut-off end of the first line segment D1 close to the second area A2 may be set as a bifurcated structure. It may be understood that, even when the cut-off end J1 of the first line segment D1 close to the second area A2 may not be extended out of the first main body V1 to form a protruding structure and only the cut-off end of the first line segment D1 close to the second area A2 may be set as a bifurcated structure, the ability of the cut-off end J1 of the first line segment D1 close to the second area A2 to accumulate electrostatic charge may be improved, thereby preventing the cut-off end J1 of the first line segment D1 close to the second area A2 from releasing static electricity to damage the first main body V1 of the first power line PVDD to a certain extent.

Further, a sacrificial structure for releasing static electricity may be provided at the cut-off end of the first line segment D1. Therefore, when too much static electricity is accumulated at the cut-off end of the first line segment D1, static electricity may be preferentially released at the sacrificial structure, thereby protecting the second line segment D2 and the first main body V1 in the first power supply voltage line PV from static electricity damage, and improving the reliability of static electricity protection at the cut-off end of the first line segment D1.

As shown in FIG. 11 and FIG. 12, the display panel may include a substrate sub, an active layer py located on one side of the substrate sub, and a multi-layer metal layer located on the side of the active layer py away from the substrate sub. The multi-layer metal layer may include a metal layer M1, a metal layer MC, a metal layer M2, a metal layer M3, and a metal layer RE arranged in a direction away from the substrate sub. The first line segment D1 may be located in at least one metal layer in the multi-layer metal layer. Different metal layers and metal layers and active layers may be isolated by insulating layers.

As shown in FIG. 11 to FIG. 12 and FIG. 23 to FIG. 28, the first line segment D1 may include a first sub-line segment D101 and a second sub-line segment D102. The first sub-line segment D101 and the second sub-line segment D102 may be arranged in different layers. The orthographic projection of the first sub-line segment D101 on the plane where the display panel is located and the orthographic projection of the second sub-line segment D102 on the plane where the display panel is located may extend in the same direction.

The second line segment D2 may include a third sub-line segment D201 and a fourth sub-line segment D202. The third sub-line segment D201 and the fourth sub-line segment D202 may be arranged in different layers. The orthographic projection of the third sub-line segment D201 on the plane where the display panel is located and the orthographic projection of the fourth sub-line segment D202 on the plane where the display panel is located may have the same extension direction, and the two may be arranged alternately.

The first sub-line segment D101 and the third sub-line segment D201 may be arranged in the same layer, and the two may have the same extension direction.

The second sub-line segment D102 and the fourth sub-line segment D202 may be arranged in the same layer, and the two may have the same extension direction.

Furthermore, referring to FIG. 11 and FIG. 12, the multi-layer metal layer may include a first metal layer (metal layer M1), a second metal layer (metal layer MC), and a third metal layer (metal layer M2) stacked in sequence in a direction away from the substrate sub. The first sub-segment D101 and the third sub-segment D201 may be located in the first metal layer (metal layer M1), the second sub-segment D102 and the fourth sub-segment D202 may be located in the second metal layer (metal layer MC), and the first main body V1 of the first power supply voltage line PV may be located in the third metal layer (metal layer M2).

It may be seen that in the first area A1, the second line segment D2 may include a third sub-segment D201 located in the first metal layer (metal layer M1) and a fourth sub-segment D201 located in the second metal layer (metal layer MC), both of which extend in the same direction and may be alternately arranged along the first direction X, and the extension direction and wiring method of the first line segment D1 may be the same as those of the second line segment D2, and the only difference may be that both ends of the first line segment D1 may be cut-off ends.

It may be understood that, when the first power supply voltage line PV may be the power supply voltage line PVDD, the first subordinate line in the first power supply voltage line PV may be usually located in the metal layer M3, and the first main body V1 may be electrically connected to the first subordinate line by switching from the metal layer M2 to the metal layer M3. When the first power supply voltage line PV may be the power supply voltage line PVEE, the first subordinate line in the first power supply voltage line PV may be usually located in the metal layer M4, and the first main body V1 may be electrically connected to the first subordinate line by switching from the metal layer M2 to the metal layer M4.

Optionally, as shown in FIG. 23 to FIG. 28, on either side of a group of second line segments D2 along the first direction X, a first sub-line segment D101 located in the first metal layer (metal layer M1) and a second sub-line segment D102 located in the second metal layer (metal layer MC) may be set to form a first line segment D1. Alternatively, a first sub-segment D101 located in the first metal layer (metal layer M1) or a second sub-segment D102 located in the second metal layer (metal layer MC) may be provided as the first segment D1 on either side of a group of second segments D2 along the first direction X.

Alternatively, in the first area A1, the first segment D1 and the second segment D2 may both be located in the first metal layer (metal layer M1).

Compared with setting the first line segment D1 and the second line segment D2 in the same metal layer, setting the second line segment D2 and the first sub-segment D1 by two sub-segments set in different layers to be arranged alternately along the first direction X may reduce the wiring density in the same metal layer of the first area A1, which may be convenient for wiring.

It may also be understood that the first sub-segment D101, the second sub-segment D102, the third sub-segment D201 and the fourth sub-segment D202 have the same extension direction, which means that they all extend from the data pin P11 of the third area A3 to the direction of the data signal line ND of the second area A2, and may be not limited to being completely parallel.

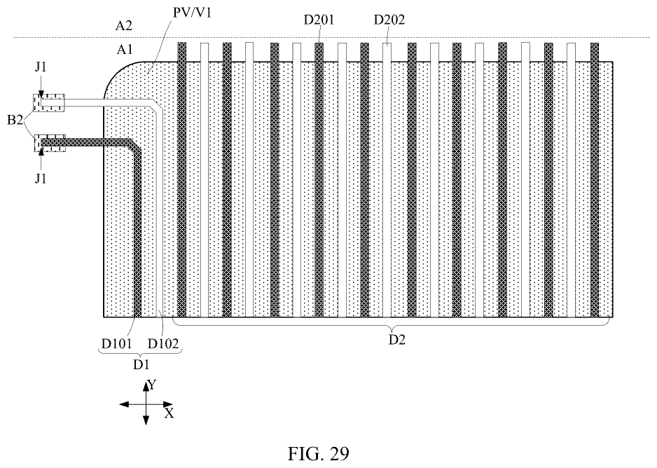

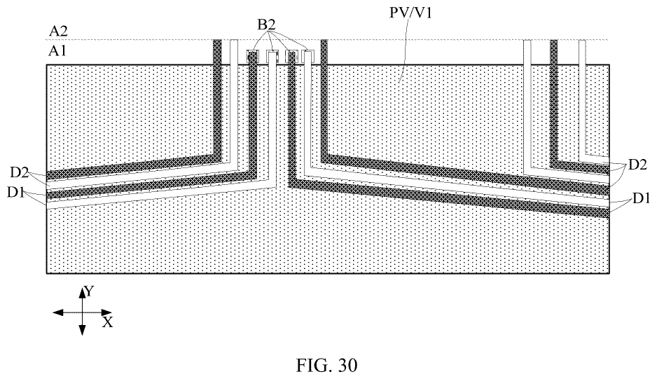

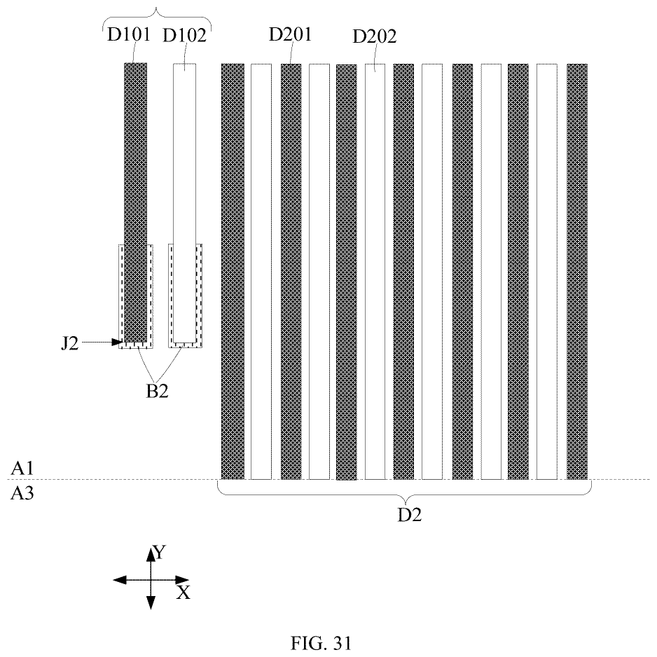

FIG. 29 shows an enlarged schematic diagram of another layout structure corresponding to the EE′ area in FIG. 22, and FIG. 30 shows an enlarged schematic diagram of another layout structure corresponding to the FF′ area in FIG. 22. As shown in FIG. 29 and FIG. 30, the display panel may further include a second conductive portion B2, and the second conductive portion B2 and the first line segment D1 may be arranged in different layers. In the direction perpendicular to the plane where the display panel may be located, the cut-off end of the first line segment D1 may at least partially overlap with the second conductive portion B2, and an insulating layer may be provided between the cut-off end of the first line segment D1 and the second conductive portion B2. The cut-off end of the first line segment D1 may include the cut-off end J1 of the first line segment D1 close to the second area A2 and the cut-off end J2 of the first line segment D1 close to the third area A2. FIG. 29 and FIG. 30 show the situation that the cut-off end J1 of the first line segment D1 close to the second area A2 overlaps with the second conductive portion B2 in the direction perpendicular to the plane where the display panel may be located, and FIG. 31 shows the situation that the cut-off end J2 of the first line segment D1 close to the third area A3 overlaps with the second conductive portion B2 in a direction perpendicular to the plane where the display panel may be located.

In this way, when the cut-off end of the first line segment D1 accumulates a lot of electrostatic charge which needs to be discharged at the tip, the insulating layer between the cut-off end of the first line segment D1 and the second conductive portion B2 may be preferentially broken down, and the electrostatic discharge may be performed to the second conductive portion B2, which may more effectively protect the second line segment D1 and the first power supply voltage line PV from electrostatic damage and further improve the reliability of electrostatic protection of the cut-off end of the first line segment D1.

Optionally, in some embodiments of the present application, the second conductive portion B2 may be located between the metal layer where the first line segment D1 is located and the base substrate sub. In this configuration, the second conductive portion B2 may be first formed on the base substrate sub, and then the first line segment D1 and the second line segment D2 may be formed on the side of the second conductive portion B2 away from the base substrate sub. Therefore, when the static electricity needs to be released at the cut-off end of the first line segment D1 during the preparation of the first line segment D1 and the second line segment D2, the cut-off end of the first line segment D1 may release static electricity to the second conductive portion B2, thereby improving the preparation yield of the display panel; and during the use of the display panel, the cut-off end of the first line segment D1 may also release static electricity to the second conductive portion B2.

In some other embodiments of the present disclosure, the second conductive portion B2 may also be located between the metal layer where the first line segment D1 is located and the substrate sub. With such a configuration, during the use of the display panel, the cut-off end of the first line segment D1 may release static electricity to the second conductive portion B2.

On the basis that the second conductive portion B2 is located between the metal layer where the first line segment D1 is located and the substrate sub, considering that the first line segment D1 may include a first sub-line segment D101 located in the first metal layer (metal layer M1) and a second sub-line segment D102 located in the second metal layer (metal layer MC), optionally, in some embodiments of the present disclosure, the second conductive portion B2 may be located in the active layer py.

Optionally, in some embodiments of the present disclosure, as shown in FIG. 29 to FIG. 31, the orthographic projection of the cut-off end of the first line segment D1 on the plane where the display panel is located may be located within the orthographic projection of the second conductive portion B2 on the plane where the display panel is located. This configuration may be beneficial for the electrostatic charge accumulated at the cut-off end of the first line segment D1 to be fully released to the second conductive portion B2.

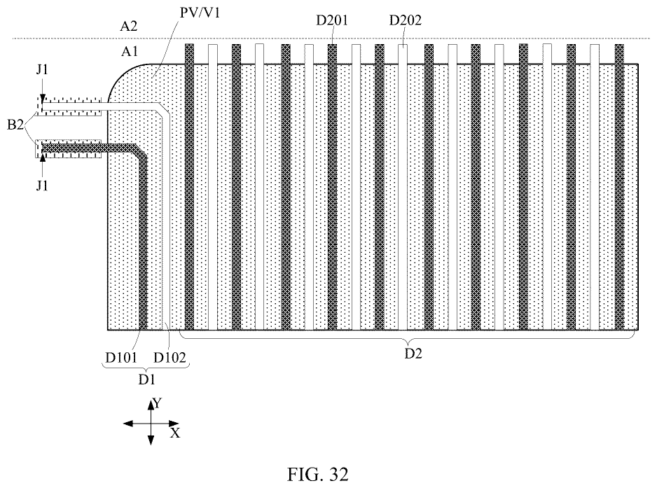

Further optionally, in some embodiments of the present disclosure, as shown in FIG. 29 to FIG. 32, especially as shown in FIG. 32 which is another enlarged schematic diagram of the layout structure corresponding to the EE′ area in FIG. 22, the second conductive portion B2 may extend along the extension direction of the first line segment D1, that is, the second conductive portion B2 may be a linear structure extending along the extension direction of the first line segment D1. Such a setting may be more conducive to the full release of the electrostatic charge accumulated at the cut-off end of the first line segment D1 to the second conductive portion B2.

It should be noted that the structural design of the first conductive portion B1 overlapping with the first line segment D1 in the first signal line S1 in the direction perpendicular to the plane where the display panel is located in the aforementioned embodiments may also be applied to the second conductive portion B2, and the linear structure of the second conductive portion B2 extending along the extension direction of the first line segment D1 may also be applied to the first conductive portion B1, which will not be repeated.

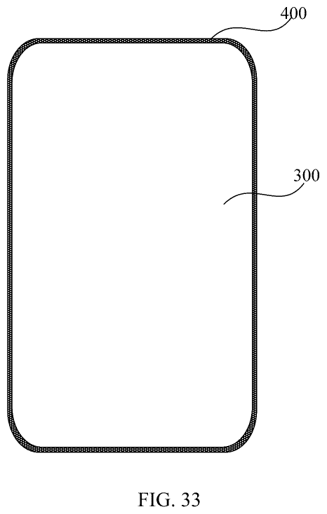

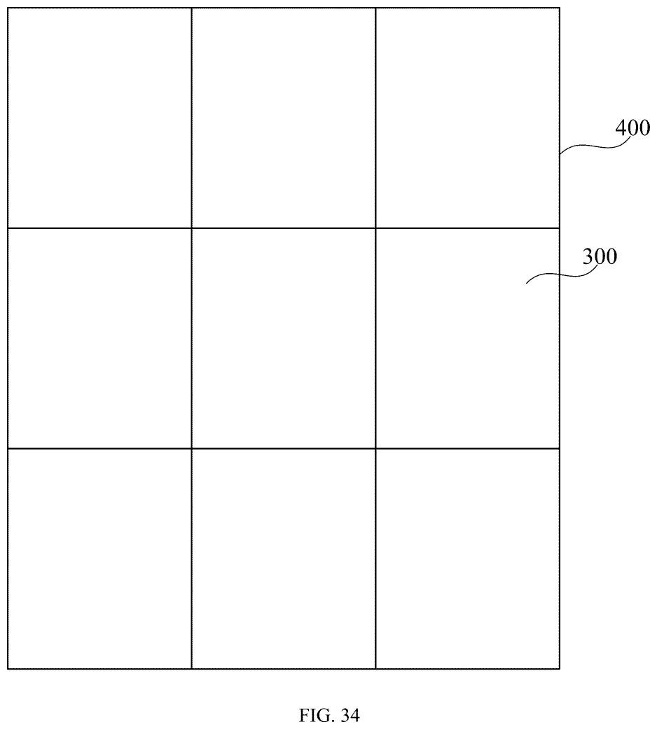

Accordingly, the present disclosure also provides a display device, as shown in FIG. 33 and FIG. 34, the display device 400 may include a display panel 300 provided by any of the aforementioned embodiments. Since the display panel 300 has been described in detail in the above embodiments, it will not be repeated here.

The display device 400 may be any electronic device with a display function, such as a touch screen, a mobile phone, a tablet computer, a laptop computer, an e-book or a TV.

It should be noted that, since the driving circuit may be set in the display area in the above embodiments to realize a borderless and full-screen design of the display panel, the display device provided in the embodiment of the present disclosure may be a spliced display device, including multiple borderless display units (i.e., the display panel 300).

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising first line segments, second line segments, and pixel circuits, wherein:
at least one end of one first line segment is a cut-off end;
two ends of one second line segment are non-cut-off ends; and
one second line segment is electrically connected to one corresponding pixel circuit;
the display panel has a first area and a second area;
the first area is located on a side of the second area close to an edge of the display panel; and
the pixel circuits are disposed in the second area; and
the first line segments are located in the first area.

2. The display panel according to claim 1, wherein:
one first line segment is connected to one corresponding second line segment;
the display panel further includes first signal lines; and
one first signal line includes one corresponding first line segment and one corresponding second line segment, wherein one end of the first line segment away from the second line segment is a cut-off end and the cut-off end of the first line segment is the cut-off end of the first signal line.

3. The display panel according to claim 2, wherein:
the display panel has a display area including the first area and the second area, and the second area also includes at least one driving circuit, wherein one driving circuit includes a shift register circuit with a multi-stage cascade arrangement and one first signal line is also electrically connected to one corresponding shift register circuit; or,
the display panel has a display area including the first area and the second area, and the second area also includes at least one driving circuit, wherein: one driving circuit includes a shift register circuit with a multi-stage cascade arrangement, the display panel further includes second signal lines extending along the second direction, and one first signal line is also electrically connected to one corresponding second signal line.

4. The display panel according to claim 2, further including pixel circuit group, wherein:
one pixel circuit group includes at least two of the pixel circuits, and the pixel circuit groups are arranged in rows along a first direction, wherein: multiple rows of pixel circuit groups are arranged along a second direction and the first direction and the second direction intersect and are parallel to the plane where the display panel is located;
the first signal lines extend along the first direction; and
in a direction perpendicular to an extending direction of one first signal line, a width of the cut-off end of the first signal line is larger than a width of other portions of the first signal line except for the cut-off end.

5. The display panel according to claim 2, further including pixel circuit group, wherein:
one pixel circuit group includes at least two of the pixel circuits, and the pixel circuit groups are arranged in rows along a first direction, wherein: multiple rows of pixel circuit groups are arranged along a second direction and the first direction and the second direction intersect and are parallel to the plane where the display panel is located;
the first signal lines extend along the first direction; and
in one first signal line, the first line segment includes a main body and bifurcated portions extending in different directions, wherein the bifurcated portions are connected to the main body and the main body is connected to one corresponding second line segment.

6. The display panel according to claim 3, further including:
pixel circuit group;
a base substrate;
an active layer located on one side of the base substrate;
a multi-layer metal layer located on a side of the active layer away from the base substrate, wherein the first signal lines are located in a metal layer of the multi-layer metal layers; and
first conductive portions,
wherein:
one pixel circuit group includes at least two of the pixel circuits, and the pixel circuit groups are arranged in rows along a first direction, wherein: multiple rows of pixel circuit groups are arranged along a second direction and the first direction and the second direction intersect and are parallel to the plane where the display panel is located;
the first signal lines extend along the first direction;
the first conductive portions and the first signal lines are arranged in different layers; and
in a direction perpendicular to the plane where the display panel is located, one first conductive portion and the first line segment in one corresponding first signal line at least partially overlap, wherein an insulating layer is provided between the first conductive portion and the first line segment in the first signal line.

7. The display panel according to claim 6, wherein:
in the direction perpendicular to the plane where the display panel is located, the cut-off end of the first signal line does not overlap with the first conductive portion.

8. The display panel according to claim 6, wherein:
the first conductive portion is located between the metal layer where the first signal line is located and the base substrate; and
the first conductive portion is located in the active layer.

9. The display panel according to claim 8, wherein:
the first conductive portion includes at least one first sub-conductive portion, wherein the at least one sub-conductive portion extends along the second direction and overlaps with the first line segment in the direction perpendicular to the plane where the display panel is located;
the second area includes a plurality of thin film transistors, wherein: the plurality of thin film transistors include a first transistor and the first transistor includes a channel region located in the active layer which overlaps with the first signal line in the direction perpendicular to the plane where the display panel is located; and
along the extension direction of the first signal line, a width of the first sub-conductive portion overlapping with the first signal line in the direction perpendicular to the plane where the display panel is located is larger than the width of the channel region of the first transistor overlapping with the first signal line in the direction perpendicular to the plane where the display panel is located.

10. The display panel according to claim 9, wherein:
the first conductive portion includes at least two first sub-conductive portions, and the at least two first sub-conductive portions are arranged along the first direction; and
the first conductive portion further includes a second sub-conductive portion connecting two adjacent first sub-conductive portions, and the second sub-conductive portion extends along the first direction.

11. The display panel according to claim 8, wherein:
the multiple types of first signal lines include first-type first signal lines and second-type first signal lines, wherein a width of the first-type first signal lines along the second direction is larger than a width of the second-type first signal lines along the second direction;
the first conductive portions include first-type first conductive portions and second-type second conductive portions, wherein one first-type first conductive portion overlaps with one corresponding first-type first signal line and one second-type first conductive portion overlaps with one corresponding second-type first signal line;
an area of the orthographic projection of the first-type first conductive portion perpendicular to the plane where the display panel is located is larger than an area of the orthographic projection of the second-type first conductive portion perpendicular to the plane where the display panel is located;
and/or, the number of the first-type first conductive portions is larger than the number of the second-type first conductive portions;
and/or, along the second direction, the first-type first conductive portion and the second-type first conductive portion at least partially do not overlap.

12. The display panel according to claim 1, wherein:
the second area includes data signal lines arranged along a first direction and extending along a second direction, wherein the first direction and the second direction intersect and are parallel to the plane where the display panel is located;
the first area is located on one side of the second area along the second direction;
the second line segments are located in the first area, and the multiple second line segments are arranged along the first direction;
the first line segments are located on at least one side of the multiple second line segments along the first direction, and the first line segments and the second line segments extend in the same direction;
the display panel also includes a third area located on a side of the first area away from the second area;
the third area includes a plurality of pins, and the plurality of pins include data pins;
one end of one second line segment is electrically connected to one corresponding data pin, and another end of the second line segment is electrically connected to one corresponding data signal line; and
two ends of one first line segment are cut-off ends.

13. The display panel according to claim 12, further including a first power voltage line, wherein:
the plurality of pins in the third area includes a first power pin, wherein the first power pin is electrically connected to the first power voltage line;
the first power voltage line includes a first subordinate line located in the second area, and a first main body and a first extension portion located in the first area, wherein: the first main body extends along the first direction; the first main body is electrically connected to the first subordinate line and is electrically connected to the first extension portion; and the first extension portion is electrically connected to the first power pin;
the first main body and the second line segment are arranged in different layers, and in the direction perpendicular to the plane where the display panel is located, the first main body and the second line segment at least partially overlap;
the first main body and the first line segment are arranged in different layers, and in the direction perpendicular to the plane where the display panel is located, the first main body and the first line segment at least partially overlap.

14. The display panel according to claim 13, wherein:
in the direction perpendicular to the plane where the display panel is located, a cut-off end of the first line segment close to the second area does not overlap with the first main body;
or
in the direction perpendicular to the plane where the display panel is located, a width of a cut-off end of the first line segment close to the second region is larger than a width of other portions of the first line segment except the cut-off end;
or
the first line segment includes a main body and bifurcated portions extending in different directions, wherein the bifurcated portions are connected to the main body.

15. The display panel according to claim 13, further including a base substrate; an active layer located on one side of the base substrate; a multi-layer metal layer located on a side of the active layer away from the base substrate, and second conductive portions, wherein:
the first line segments are located on at least one metal layer of the multi-layer metal layer;
the second conductive portions and the first line segments are arranged in different layers; and
in the direction perpendicular to the plane where the display panel is located, the cut-off end of one first line segment at least partially overlaps with one corresponding second conductive portion, and an insulating layer is provided between the cut-off end of the first line segment and the corresponding second conductive portion.

16. The display panel according to claim 15, wherein:
an orthographic projection of the cut-off end of the first line segment on the plane where the display panel is located within an orthographic projection of the corresponding second conductive portion on the plane where the display panel is located.

17. The display panel according to claim 16, wherein:
the second conductive portion extends along an extending direction of the first line segment.

18. The display panel according to claim 13, wherein:
one first line segment includes a first sub-line segment and a second sub-line segment, wherein: the first sub-line segment and the second sub-line segment are arranged in different layers, and an orthographic projection of the first sub-line segment on the plane where the display panel is located and the orthographic projection of the second sub-line segment on the plane where the display panel is located have the same extension direction;
one second line segment includes a third sub-line segment and a fourth sub-line segment, wherein: the third sub-line segment and the fourth sub-line segment are arranged in different layers; and an orthographic projection of the third sub-line segment on the plane where the display panel is located and an orthographic projection of the fourth sub-line segment on the plane where the display panel is located have the same extension direction, and the two are alternately arranged;
the first sub-line segment and the third sub-line segment are arranged in the same layer, and the two extend in the same direction; and
the second sub-line segment and the fourth sub-line segment are arranged in the same layer, and the two extend in the same direction.

19. The display panel according to claim 18, further including a base substrate; an active layer located on one side of the base substrate; and a multi-layer metal layer located on a side of the active layer away from the base substrate, wherein:
the multi-layer metal layer includes a first metal layer, a second metal layer and a third metal layer stacked in sequence along a direction away from the base substrate;
the first sub-line segment and the third sub-line segment are located in the first metal layer; and
the second sub-line segment and the fourth sub-line segment are located in the second metal layer, and the first main body is located in the third metal layer.

20. A display device comprising a display panel, wherein:
the display panel includes first line segments, second line segments, and pixel circuits, wherein:
at least one end of one first line segment is a cut-off end;
two ends of one second line segment are non-cut-off ends; and
one second line segment is electrically connected to one corresponding pixel circuit;
the display panel has a first area and a second area;
the first area is located on a side of the second area close to an edge of the display panel; and
the pixel circuits are disposed in the second area; and
the first line segments are located in the first area.
